(19) United States
(12) Patent Application Publication
(10) Pub. No.: US 2026/0076232 A1
(43) Pub. Date: Mar. 12, 2026

(54) SEMICONDUCTOR STRUCTURE

(71) Applicant: MEDIATEK INC., Hsinchu City (TW)

(72) Inventors: Sang-Mao CHIU, Hsinchu City (TW); Chi-Yuan CHEN, Hsinchu City (TW); Shih-Chin LIN, Hsinchu City (TW); Yi-Ting KUO, Hsinchu City (TW)

(21) Appl. No.: 19/304,929

(22) Filed: Aug. 20, 2025

Related U.S. Application Data
(60) Provisional application No. 63/691,410, filed on Sep. 6, 2024.

(51) Int. Cl. H01L 23/498

(52) U.S. Cl. CPC H10W 70/65; H10W 70/685

(57) ABSTRACT

A semiconductor structure is provided. The semiconductor structure includes a substrate. The substrate includes a first core having a first top surface and a first bottom surface. First dielectric layers are disposed on the first top surface and the first bottom surface of the first core. The substrate has a first hole passing through the first core. In addition, the substrate has a second hole passing through the first core and the first dielectric layers.

### CROSS REFERENCE TO RELATED APPLICATIONS

This application claims the benefit of U.S. Provisional Application No. 63/691,410, filed on Sep. 6, 2024, the entirety of which is incorporated by reference herein.

### BACKGROUND OF THE DISCLOSURE

### Field of the Disclosure

The present disclosure relates to a semiconductor structure and, in particular, it relates to a package substrate having through hole conductive components of different lengths.

### Description of the Related Art

In order to ensure miniaturization and multi-functionality of electronic products and communication devices, it is desired that semiconductor packages be small in size, support multi-pin connection, operate at high speeds, and have high functionality. In recent years, demand has increased for semiconductor package structures with a small size, a high I/O pad-density, high operation frequencies, better functionality, and better electrical performance and reliability, all at a low cost. However, in package substrates, there is a tradeoff between power integrity and signal integrity.

Thus, a novel package substrate is desirable.

### BRIEF SUMMARY OF THE DISCLOSURE

An embodiment of the present disclosure provides a semiconductor structure. The semiconductor structure includes a substrate. The substrate includes a first core having a first top surface and a first bottom surface. First dielectric layers are disposed on the first top surface and the first bottom surface of the first core. The substrate has a first hole passing through the first core, and a second hole passing through the first core and the first dielectric layers.

An embodiment of the present disclosure provides a semiconductor structure. The semiconductor structure includes a substrate. The substrate includes a core structure. The core structure includes at least two cores and at least three first dielectric layers stacked on each other. The at least two cores are arranged in such a way that they alternate with the at least three first dielectric layers. The substrate has a first hole passing through the first core and one of the at least three first dielectric layers, and a second hole passing through the first core and all the first dielectric layers.

### BRIEF DESCRIPTION OF THE DRAWINGS

The present disclosure can be more fully understood by reading the subsequent detailed description and examples with references made to the accompanying drawings, wherein:

FIG. 1 is a schematic cross-sectional view of a semiconductor structure in accordance with some embodiments of the disclosure;

FIG. 2 is a schematic cross-sectional view of a semiconductor structure in accordance with some embodiments of the disclosure;

FIG. 3 is a schematic cross-sectional view of a semiconductor structure in accordance with some embodiments of the disclosure;

FIG. 4 is a schematic cross-sectional view of a semiconductor structure in accordance with some embodiments of the disclosure;

FIG. 5 is a schematic cross-sectional view of a semiconductor structure in accordance with some embodiments of the disclosure;

FIG. 6 is a schematic cross-sectional view of a semiconductor structure in accordance with some embodiments of the disclosure;

FIG. 7 is a schematic cross-sectional view of a semiconductor structure in accordance with some embodiments of the disclosure;

FIG. 8 is a schematic cross-sectional view of a semiconductor structure in accordance with some embodiments of the disclosure;

FIG. 9 is a schematic cross-sectional view of a semiconductor structure in accordance with some embodiments of the disclosure;

FIG. 10 is a schematic cross-sectional view of a semiconductor structure in accordance with some embodiments of the disclosure;

FIG. 11 is a schematic cross-sectional view of a semiconductor structure in accordance with some embodiments of the disclosure;

FIG. 12 is a schematic cross-sectional view of a semiconductor structure in accordance with some embodiments of the disclosure;

FIG. 13 is a schematic cross-sectional view of a semiconductor structure in accordance with some embodiments of the disclosure;

FIG. 14 is a schematic cross-sectional view of a semiconductor structure in accordance with some embodiments of the disclosure;

FIG. 15 is a schematic cross-sectional view of a semiconductor structure in accordance with some embodiments of the disclosure; and

FIG. 16 is a schematic cross-sectional view of a semiconductor structure in accordance with some embodiments of the disclosure.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

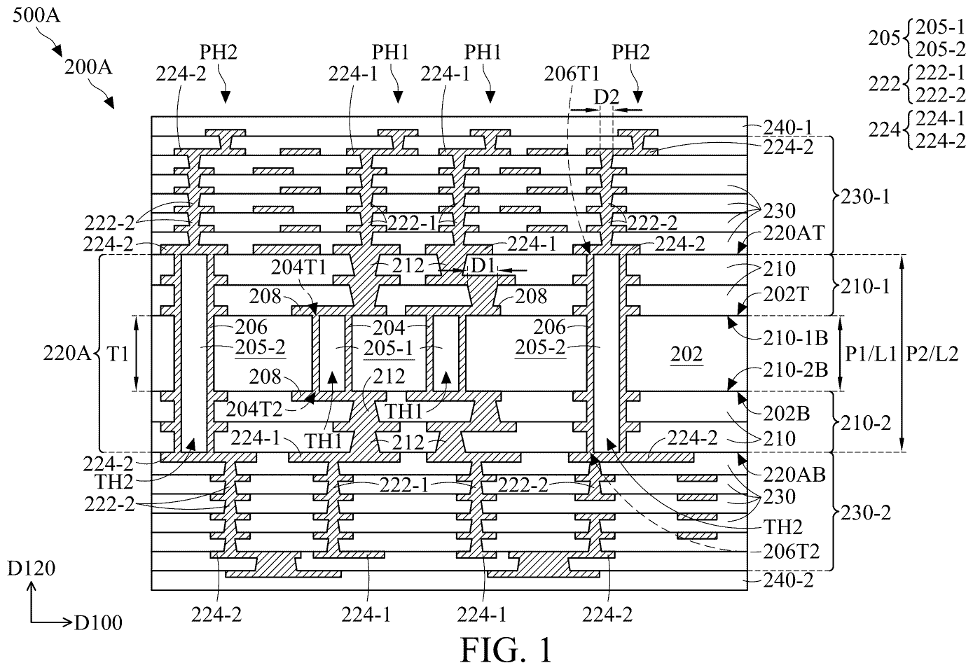

FIG. 1 is a schematic cross-sectional view of a semiconductor structure 500A in accordance with some embodiments of the disclosure. In FIG. 1 and the following figures, direction D100 is defined as horizontal directions (also regarded as the extending directions of conductive layers and/or conductive traces), and direction D120 is defined as a vertical direction (also regarded as the extending direction of the through via and/or vias).

The semiconductor structure 500A includes a substrate 200A. For example, the substrate 200A may include a multi-layered package substrate (e.g., a flip-chip ball grid array (FCBGA) substrate). The substrate 200A may provide mechanical support and electrical connections between integrated circuit (IC) chips and conductive bumps attached to the top and bottom surfaces of the substrate 200A. The substrate 200A may have various types including, for example, cored substrates, including thin core, thick core (e.g., laminate BT (bismaleimide-triazine resin) or FR-4 type fibrous board material), and laminate core. Alternatively, the cored package substrates, for example, can be built up layer by layer around a central core, with layers of conductive material (usually copper) separated by layers of insulating dielectric, with interlayer connections being formed with through holes or vias (microvias).

In some embodiments, the substrate 200A includes a core structure 220A and substrate redistribution layers 230-1 and 230-2. In addition, the core structure 220A includes a single core 202 and core redistribution layers 210-1 and 210-2. In this embodiment, the substrate 200A may also be called a multi-layer single core substrate.

As shown in FIG. 1, the core 202 has a top surface 202T and a bottom surface 202B. In some embodiments, the core 202 may be formed of polypropylene, prepreg (PP), FR-4 and/or other epoxy laminate material.

The core redistribution layers 210-1 and 210-2 are disposed on the top surface 202T and the bottom surface 202B of the core 202, respectively. In some embodiments, each of the core redistribution layers 210-1 and 210-2 includes one or more conductive layers 208, one or more vias 212 disposed in one or more dielectric layers 210.

In some embodiments, the dielectric layers 210 of the core redistribution layers 210-1 and 210-2 are symmetrically (or asymmetrically) disposed the top surface 202T and the bottom surface 202B of the core 202. For example, the number of dielectric layers 210 of the core redistribution layer 210-1 is the same as (or different from) the number of dielectric layers 210 of the core redistribution layers 210-2. In this embodiments, the dielectric layers 210 of the core redistribution layers 210-1 and 210-2 are symmetrically disposed the top surface 202T and the bottom surface 202B of the core 202. Each of the core redistribution layers 210-1 and 210-2 include two dielectric layers 210. In some embodiments, the dielectric layers 210 may be formed of prepreg (PP). The core 202 and the dielectric layers 210 may contain glass fibers. In some embodiments, the dielectric layers 210 may be formed using a lamination process.

It should be noted that the number of vias 212, the number of conductive layers 208 and the number of dielectric layers 210 of the core redistribution layers 210-1 and 210-2 shown in FIG. 1 are only an example and is not a limitation to the present disclosure.

As shown in FIG. 1, the core structure 220A of the substrate 200A has separated holes TH1 and TH2 (or through holes TH1 and TH2) embedded it. In some embodiments, the holes TH1 are formed passing through the core 202 only. In addition, the holes TH2 are formed passing through the core 202 and all the dielectric layers 210 on the top surface 202T and the bottom surface 202B of the core 202. In some embodiments, in the direction D120, the depth P1 of the hole TH1 is substantially equal to the thickness T1 of the core 202. In addition, the depth P2 of the hole TH2 is substantially equal to the total thickness of the core 202 and the core redistribution layers 210-1 and 210-2. Therefore, the depth P1 of the hole TH1 is smaller than the depth P2 of the hole TH2. In some embodiments, the holes TH1 and TH2 are formed by a drilling process (e.g., mechanical drilling).

The conductive material 204 is disposed in the hole TH1, and the conductive material 206 is disposed in the hole TH2. In some embodiments, as shown in FIG. 1, each of the conductive material portions 204, 206 may be formed as a thin conductive layer lining inner walls of the hole TH1 and the hole TH2. The conductive material 204 in the hole TH1 and the conductive material 206 in the hole TH2 may have a hollow pillar shape. The conductive materials 204 and 206 may also be called through hole conductive components 204 and 206.

In some embodiments, two terminals 204T1, 204T2 of the conductive material 204 in the hole TH1 are not aligned with two corresponding terminals 206T1, 206T2 of the conductive material 206 in the hole TH2 in the direction D100. For example, the two terminals 204T1, 204T2 of the conductive material 204 in the hole TH1 may be close to the top surface 202T and the bottom surface 202B of the core 202, respectively. In addition, the two terminals 204T1, 204T2 of the conductive material 204 in the hole TH1 may be exposed from the top surface 202T and the bottom surface 202B of the core 202, respectively. In some embodiments, the two terminals 206T1, 206T2 of the conductive material 206 in the hole TH2 may be close to the top surface 220AT and the bottom surface 220AB of the core structure 220A, respectively. In addition, the two terminals 206T1, 206T2 of the conductive material 206 in the hole TH2 may be exposed from the top surface 220AT and the bottom surface 220AB of the core structure 220A, respectively.

In some embodiments, the terminal 204T1 of the conductive material 204 in the hole TH1 and the terminal 206T1 of the conductive material 206 in the hole TH2 are close to opposite surfaces of any of the dielectric layers 210 of the core redistribution layer 210-1. For example, the terminal 204T1 of the conductive material 204 in the hole TH1 is close to a surface (also an inner surface 210-1B of the core redistribution layer 210-1) of the inner dielectric layer 210 of the core redistribution layer 210-1 that is close to the top surface 202T of the core 202. The terminal 206T1 of the conductive material 206 in the hole TH2 is close to a surface (also the top surface 220AT) of the outer dielectric layer 210 of the core redistribution layer 210-1 that is close to the top surface 220AT of the core structure 220A.

In other words, the terminal 204T1 of the conductive material 204 in the hole TH1 is close to the inner surface (also the inner surface 210-1B of the core redistribution layer 210-1) of one of the dielectric layers 210 of the core redistribution layer 210-1 that is close to the core 202. The terminal 206T1 of the conductive material 206 in the hole TH2 is close to the outer surface (also the top surface 220AT) of the one of the dielectric layers 210 of the core redistribution layer 210-1 that is away from the core 202.

Similarly, the terminal 204T2 of the conductive material 204 in the hole TH1 and the terminal 206T2 of the conductive material 206 in the hole TH2 are close to opposite surfaces of any of the dielectric layers 210 of the core redistribution layer 210-2. For example, the terminal 204T2 of the conductive material 204 in the hole TH1 is close to a surface (also an inner surface 210-2B of the core redistribution layer 210-2) of the inner dielectric layer 210 of the core redistribution layer 210-2 that is close to the bottom surface 202B of the core 202. The terminal 206T2 of the conductive material 206 in the hole TH2 is close to a surface (also the bottom surface 220AB) of the outer dielectric layer 210 of the core redistribution layer 210-2 that is close to the bottom surface 220AB of the core structure 220A.

In other words, the terminal 204T2 of the conductive material 204 in the hole TH1 is close to the inner surface (also the inner surface 210-2B of the core redistribution layer 210-2) of one of the dielectric layers 210 of the core redistribution layer 210-2 that is close to the core 202. The terminal 206T1 of the conductive material 206 in the hole TH2 is close to the outer surface (also the bottom surface 220AB) of the one of the dielectric layers 210 of the core redistribution layer 210-1 that is away from the core 202.

In some embodiments, in the direction D120, a dimension L1 of the conductive material 204 is substantially equal to the thickness of the core 202. In addition, a dimension L2 of the conductive material 206 is substantially equal to the total thickness of the core 202 and the core redistribution layers 210-1 and 210-2. Therefore, the dimension L1 of the conductive material 204 is smaller than the dimension L2 of the conductive material 206.

In some embodiments, the conductive materials 204 and 206 include copper or nickel-copper and are formed by a plating process, such as chemical plating, electroplating or electro-less plating. For example, the conductive materials 204 and 206 may also be called plated through holes (PTHs) 204 and 206.

As shown in FIG. 1, the semiconductor structure 500A further includes a non-conductive material 205 (including non-conductive material portions 205-1, 205-2) filling the remaining spaces of the holes TH1 and TH2 and surrounded by the conductive materials 204, 206. For example, the non-conductive material portion 205-1 may fill the hole TH1 and be surrounded by the conductive material 204. In addition, the non-conductive material portion 205-2 may fill the hole TH2 and be surrounded by the conductive material portion 206. In some embodiments, the non-conductive material 205 includes epoxy resin, such as an ink.

As shown in FIG. 1, the core structure 220A further includes conductive layers 208 formed directly on the top surface 202T and the bottom surface 202B of the core 202, respectively. In some embodiments, the conductive layers 208 may cover the holes TH1, the conductive material 204 lining the inner walls of the holes TH1 and the non-conductive material 205 filling the holes TH1. For example, the conductive layers 208 may fully cover the holes TH1 and the conductive material 204 and the non-conductive material 205 in the holes TH1. In addition, the conductive layers 208 may be connected (coupled) to the conductive material 204 lining the inner wall walls of the holes TH1.

As shown in FIG. 1, the conductive layers 208 may partially cover the top surface 202T and the bottom surface 202B of the core 202. In addition, the dielectric layers 210 of the core redistribution layers 210-1 and 210-2 may be disposed on the conductive layers 208, respectively. In addition, the dielectric layers 210 of the core redistribution layers 210-1 and 210-2 may cover the conductive layers 208, the holes TH1 and TH2, the conductive material 204 lining the inner walls of the holes TH1, the conductive material 206 lining the inner walls of the holes TH2, and the non-conductive material 205 filling the holes TH1 and TH2.

In some embodiments, the conductive layer 208 at each of levels of the core redistribution layers 210-1 and 210-2 may include a set of conductive traces (not shown) or conductive planes (also called ground planes) (not shown). In some embodiments, the conductive layers 208 include a conductive material, such as metals including copper, gold, silver, or other applicable metals. For example, the conductive layers 208 may be copper traces 208.

As shown in FIG. 1, the vias 212 disposed in the dielectric layers 210 of the core redistribution layers 210-1 and 210-2. The vias 212 may be formed passing through the dielectric layers 210 of the core redistribution layers 210-1 and 210-2 to be coupled to the conductive layers 208. In some embodiments, the vias 212 may be formed by laser-drilling.

It is note that the conductive layers 208 and the vias 212 are arranged side-by-side with and separated from the conductive material 206 lining the inner walls of the holes TH2 in the direction D100.

As shown in FIG. 1, the semiconductor structure 500A further includes substrate redistribution layers (RDLs) 230-1 and 230-2. The substrate redistribution layers 230-1 and 230-2 are disposed on the core redistribution layers 210-1 and 210-2, respectively. In some embodiments, each of the substrate redistribution layers 230-1 and 230-2 includes one or more conductive layers 224 (including conductive layers 224-1 and 224-2), one or more vias 222 (including vias 222-1 and 222-2) disposed in one or more dielectric layers 230. It should be noted that the number of vias 222, the number of conductive layers 224 and the number of dielectric layers 230 shown in FIG. 1 are only an example and is not a limitation to the present disclosure.

In some embodiments, the substrate redistribution layers 230-1 and 230-2 are connected to (or coupled to) the conductive material 204 in the holes TH1 and the conductive material 206 in the holes TH2. More specifically, the conductive material 204 in the holes TH1 may be coupled to the conductive layers 208 of the core redistribution layers 210-1 and 210-2. The conductive layers 208 may be connected to (or coupled to) the corresponding vias 212 in the dielectric layers 210 of the core redistribution layers 210-1 and 210-2. The vias 212 located in the dielectric layers 210 may be connected to (or coupled to) the vias 222 and the conductive layers 224 in the substrate redistribution layers 230-1 and 230-2. In other words, the conductive material 204 in the holes TH1 may be coupled to the substrate redistribution layers 230-1 and 230-2 through the conductive layers 208 and the vias 212 of the core redistribution layers 210-1 and 210-2. In addition, the conductive material 206 in the holes TH2 may be directly connected to (or coupled to) the substrate redistribution layers 230-1 and 230-2 without using the conductive layers 208 and the vias 212 of the core redistribution layers 210-1 and 210-2.

As shown in FIG. 1, the conductive layers 224-1 and 224-2 may partially cover the top surface 220AT and the bottom surface 220AB of the core structure 220A. In addition, the dielectric layers 230 of the substrate redistribution layers 230-1 and 230-2 may be disposed on the conductive layers 224-1 and 224-2, respectively. In addition, the dielectric layers 230 of the substrate redistribution layers 230-1 and 230-2 may cover the conductive layers 224-1 and 224-2.

In some embodiments, the conductive layers 224-1 and 224-2 at each of levels of the substrate redistribution layers 230-1 and 230-2 may include a set of conductive traces (not shown) or conductive planes (also called ground planes) (not shown). In some embodiments, the conductive layer 224-1 is directly coupled to the vias 212 of the core redistribution layers 210-1 and 210-2 at the interface (also positioned at the top surface 220AT of the core structure 220A) between the core redistribution layer 210-1 and the corresponding substrate redistribution layers 230-1 and the interface (also positioned at the bottom surface 220AB of the core structure 220A) between the core redistribution layer 210-2 and the corresponding substrate redistribution layers 230-2. In some embodiments, the conductive layer 224-2 is directly coupled to the conductive material 206 in the hole TH2. In some embodiments, the conductive layers 208 and the conductive layers 224 may have the same or similar materials and processes.

As shown in FIG. 1, the vias 222-1 and 222-2 are disposed in the dielectric layers 230 of the substrate redistribution layers 230-1 and 230-2. The vias 222-1 may be formed passing through the dielectric layers 230 of the substrate redistribution layers 230-1 and 230-2 to be coupled to the conductive material 204 in the hole TH1 by the conductive layers 208 covered by the dielectric layers 210 and the conductive layers 224-1 covered by the dielectric layers 230. The vias 222-2 may be formed passing through the dielectric layers 230 of the substrate redistribution layers 230-1 and 230-2 to be coupled to the conductive material 206 in the hole TH2 only by the conductive layers 224-1 covered by the dielectric layers 230. In some embodiments, the vias 212 and the vias 222 may have the same or similar materials and processes.

In some embodiments, the dielectric layers 230 of the substrate redistribution layers 230-1 and 230-2 are symmetrically (or asymmetrically) disposed the top surface 220AT and the bottom surface 220AB of the core structure 220A. In some embodiments, at least two dielectric layers 230 are disposed on the top surface 220AT and the bottom surface 220AB of the core structure 220A and connected to the outer dielectric layers 210 of the core redistribution layers 210-1 and 210-2. For example, the number of dielectric layers 230 of the substrate redistribution layers 230-1 is the same as (or different from) the number of dielectric layers 230 of the substrate redistribution layers 230-2.

In some embodiments, the dielectric layers 210 and 230 are made of different materials and formed by different processes. In this embodiment, the dielectric layer 230 includes Ajinomoto Build-Up Film (ABF). In this embodiment, the dielectric layer 230 may be formed by coating or lamination.

In some embodiments, the dielectric constant of the dielectric layer 230 may be different from the dielectric constant of the dielectric layer 210. For example, the dielectric constant of the dielectric layer 230 may be lower than the dielectric constant of the dielectric layer 210.

Due to the characteristics of materials and fabrication processes of the dielectric layers 210 and 230, the core redistribution layers 210-1 and 210-2 and the substrate redistribution layers 230-1 and 230-2 may have different routing densities. For example, when the dielectric layer 210 is formed of prepreg (PP) and the dielectric layer 230 is formed of ABF, the routing density of the substrate redistribution layers 230-1 and 230-2 may be larger than the routing density of the core redistribution layers 210-1 and 210-2.

The conductive traces of the conductive layers 208 of the core redistribution layers 210-1 and 210-2 may have first minimum line width and spacing, and the conductive traces of the conductive layers 224 of the substrate redistribution layers 230-1 and 230-2 may have second minimum line width and spacing smaller than the first minimum line width and spacing. In addition, the vias 212 of the core redistribution layers 210-1 and 210-2 may have a first diameter D1, and the vias 222 of the substrate redistribution layers 230-1 and 230-2 may have a second diameter D2 smaller than the first diameter D1.

As shown in FIG. 1, the semiconductor structure 500A further includes solder mask layers 240-1 and 240-2 disposed over the corresponding substrate redistribution layers 230-1 and 230-2. In some embodiments, the solder mask layers 240-1 and 240-2 may cover the conductive layers 224 on the outermost dielectric layers 230 of the substrate redistribution layers 230-1 and 230-2. In addition, the solder mask layers 240-1 and 240-2 may have openings (not shown) to expose corresponding conductive pads (not shown). In some embodiments, the solder mask layers 240-1 and 240-2 may include an epoxy resin.

In some embodiments, the core structure 220A of the semiconductor structure 500A including the dielectric layers 210 which is formed of, example, prepreg (PP), may improve the mechanical strength of the core structure 220A to withstand various external forces without breaking or yielding.

In some embodiments, the substrate 200A of the semiconductor structure 500A provides various types of conductive routings for power transmission and signal transmission. In some embodiments, the conductive material 204 in the hole TH1 passing through the core 202 of the core structure 220A, the conductive traces of the conductive layer 208 and the vias 212 of the core redistribution layers 210-1 and 210-2, and the conductive traces of the conductive layer 224-1 and the vias 222-1 of the substrate redistribution layers 230-1 and 230-2 may form a conductive routing PH1 (also called the power routing PH1) for power transmission. For example, the power routing PH1 may include positive power supply voltage VDD, ground power supply voltage VSS, overdriven voltage signals (e.g., signals greater than VDD), negative power supply voltage signals, and other power supply voltage signals. In some embodiments, corresponding to the material and process characteristics of the dielectric layers 210 and 230, the routing density of the conductive routing PH1 in the core redistribution layers 210-1 and 210-2 is lower than that of the conductive routing PH1 in the substrate redistribution layers 230-1 and 230-2. For example, the conductive traces of the conductive layer 208 of the core redistribution layers 210-1 and 210-2 have the wider minimum line width and larger spacing than the conductive traces of the conductive layer 224-1 of the conductive routing PH1 in the substrate redistribution layers 230-1 and 230-2. Moreover, the diameter D1 of the vias 212 of the conductive routing PH1 in the core redistribution layers 210-1 and 210-2 is larger than the diameter D2 of the vias 222-1 of the conductive routing PH1 in the substrate redistribution layers 230-1 and 230-2. Therefore, the conductive routing PH1 has improved power integrity and is suitable for power transmission.

In addition, the conductive material 206 in the hole TH2 passing through the core structure 220A, and the conductive traces of the conductive layer 224-2 and the vias 222-2 of the substrate redistribution layers 230-1 and 230-2 may form a conductive routing PH2 for signal transmission (also called the signal routing PH2). Since the conductive material 206 is formed in the hole TH2 passing through the core 202 and the whole dielectric layers 210 of the core redistribution layers 210-1 and 210-2, the conductive routing PH2 may have fewer interfaces between the vias and the conductive traces of the redistribution layers (e.g., the conductive routing PH2 may be formed without the conductive traces of the conductive layer 208 and the vias 212 of the core redistribution layers 210-1 and 210-2). Therefore, the conductive routing PH2 has improved signal integrity and is suitable for signal transmission.

Since the core structure 220A of the substrate 200A of the semiconductor structure 500A is a single-core structure composed of the single core 202 and the dielectric layer 210 disposed on opposite surfaces of the core 202 and formed of prepreg (PP), the mechanical strength of the substrate 200A is improved. In addition, the conductive material 204 passing through the core 202 only may form the conductive routing PH1 suitable for power transmission. The conductive material 206 passing through the core structure 220A may form the conductive routing PH2 suitable for signal transmission. Therefore, the semiconductor structure 500A can balance between power integrity and signal integrity.

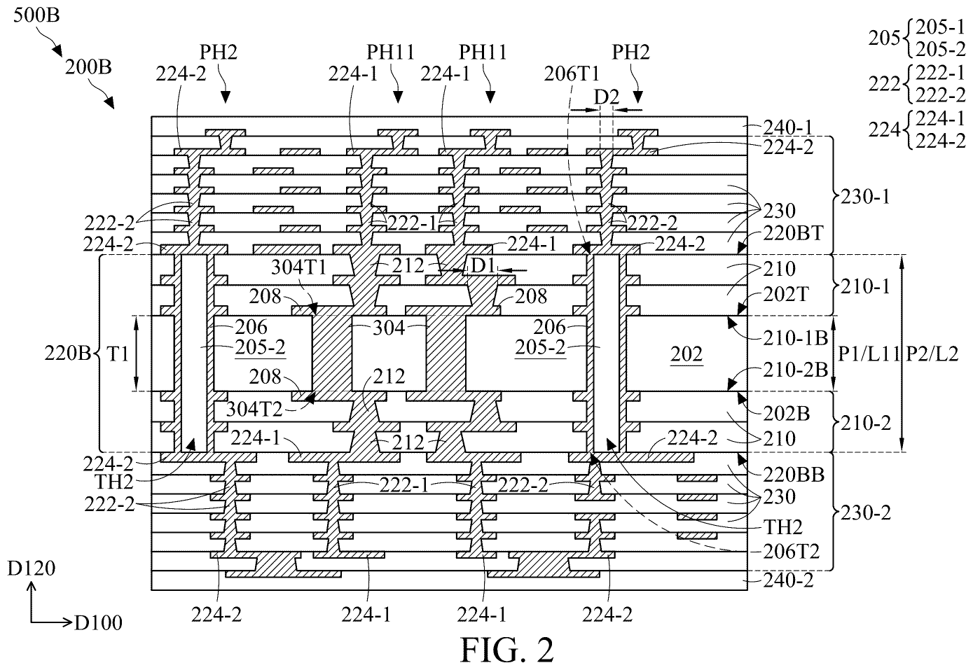

FIG. 2 is a schematic cross-sectional view of a semiconductor structure 500B in accordance with some embodiments of the disclosure. Elements of the embodiments hereinafter, that are the same or similar as those previously described with reference to FIG. 1, are not repeated for brevity.

As shown in FIGS. 1 and 2, the difference between the semiconductor structure 500A and the semiconductor structure 500B at least includes that a substrate 200B of the semiconductor structure 500B includes a conductive material 304 formed as a conductive solid pillar filled in the hole TH1 of a core structure 220B. The conductive material 304 also called through hole conductive components 304.

In some embodiments, the size (e.g., the diameter) of the hole TH1 of the semiconductor structure 500B is typically smaller than the size (e.g., the diameter) of the hole TH1 of the semiconductor structure 500A because the conductive material 304 is required to completely fill the hole TH1. Alternatively, the holes TH1 of the semiconductor structures 500A and 500B may have the same size (e.g., the diameter), according to the designs, For the requirement of signal integrity, the through hole conductive components 304 will be designed located outside the die shadow.

The conductive material 304 in the hole TH1 may have a solid pillar shape. The conductive material 304 may also be called a conductive solid pillar 304. Therefore, there is no non-conductive material 205 disposed in the hole TH1. Two terminals 304T1 and 304T2 of the conductive material 304 in the hole TH1 may be close to the top surface 202T and the bottom surface 202B of the core 202, respectively. In addition, the two terminals of the conductive material 304 in the hole TH1 may be exposed from the top surface 202T and the bottom surface 202B of the core 202, respectively.

In some embodiments, the terminal 304T1 of the conductive material 304 in the hole TH1 and the terminal 206T1 of the conductive material 206 in the hole TH2 are close to opposite surfaces of any of the dielectric layers 210 of the core redistribution layer 210-1. For example, the terminal 304T1 of the conductive material 304 in the hole TH1 is close to a surface (also an inner surface 210-1B of the core redistribution layer 210-1) of the inner dielectric layer 210 of the core redistribution layer 210-1 that is close to the top surface 202T of the core 202. The terminal 206T1 of the conductive material 206 in the hole TH2 is close to a surface (also the top surface 220BT) of the outer dielectric layer 210 of the core redistribution layer 210-1 that is close to the top surface 220BT of the core structure 220B.

In other words, the terminal 304T1 of the conductive material 304 in the hole TH1 is close to an inner surface (also the inner surface 210-1B of the core redistribution layer 210-1) of one of the dielectric layers 210 of the core redistribution layer 210-1 that is close to the core 202. The terminal 206T1 of the conductive material 206 in the hole TH2 is close to an outer surface (also the top surface 220BT) of the one of the dielectric layers 210 of the core redistribution layer 210-1 that is away from the core 202.

Similarly, the terminal 304T2 of the conductive material 304 in the hole TH1 and the terminal 206T2 of the conductive material 206 in the hole TH2 are close to opposite surfaces of any of the dielectric layers 210 of the core redistribution layer 210-2. For example, the terminal 304T2 of the conductive material 304 in the hole TH1 is close to a surface (also an inner surface 210-2B of the core redistribution layer 210-2) of the inner dielectric layer 210 of the core redistribution layer 210-2 that is close to the bottom surface 202B of the core 202. The terminal 206T2 of the conductive material 206 in the hole TH2 is close to a surface (also the bottom surface 220BB) of the outer dielectric layer 210 of the core redistribution layer 210-2 that is close to the bottom surface 220BB of the core structure 220B.

In other words, the terminal 304T2 of the conductive material 304 in the hole TH1 is close to an inner surface (also the inner surface 210-2B of the core redistribution layer 210-2) of one of the dielectric layers 210 of the core redistribution layer 210-2 that is close to the core 202. The terminal 206T1 of the conductive material 206 in the hole TH2 is close to an outer surface (also the bottom surface 220BB) of the one of the dielectric layers 210 of the core redistribution layer 210-1 that is away from the core 202.

In some embodiments, in the direction D120, a dimension L11 of the conductive material 304 is substantially equal to the thickness of the core 202. In addition, a dimension L2 of the conductive material 206 is substantially equal to the total thickness of the core 202, and the core redistribution layers 210-1 and 210-2. Therefore, the dimension L11 of the conductive material 304 is smaller than the dimension L2 of the conductive material 206.

In some embodiments, the conductive materials 204, 304 and 206 are formed of the same or similar materials and fabricated in the same or similar process.

As shown in FIG. 2, the conductive layers 208 may fully cover the holes TH1 and the conductive material 304 and the non-conductive material 205 in the holes TH1. In addition, the conductive layers 208 may be connected (coupled) to the conductive material 304 lining the inner wall walls of the holes TH1.

In some embodiments, the substrate redistribution layers 230-1 and 230-2 are connected to (or coupled to) the conductive material 304 in the holes TH1. More specifically, the conductive material 304 in the holes TH1 may be the conductive material 204 in the holes TH1 may be coupled to the conductive layers 208 of the core redistribution layers 210-1 and 210-2.

In the substrate 200B of the semiconductor structure 500B, the conductive material 304 in the hole TH1 passing through the core of the core structure 220A, the conductive traces of the conductive layer 208 and the vias 212 of the core redistribution layers 210-1 and 210-2, and the conductive traces of the conductive layer 224-1 and the vias 222-1 of the substrate redistribution layers 230-1 and 230-2 may form a conductive routing PH11 (also called the power routing PH11) for power transmission.

In some embodiments, corresponding to the material and process characteristics of the dielectric layers 210 and 230, the routing density of the conductive routing PH11 in the core redistribution layers 210-1 and 210-2 is lower than that of the conductive routing PH11 in the substrate redistribution layers 230-1 and 230-2. For example, the conductive traces of the conductive layer 208 of the core redistribution layers 210-1 and 210-2 have the wider minimum line width and larger spacing than the conductive traces of the conductive layer 224-1 of the conductive routing PH11 in the substrate redistribution layers 230-1 and 230-2. Moreover, the diameter D1 of the vias 212 of the conductive routing PH11 in the core redistribution layers 210-1 and 210-2 is larger than the diameter D2 of the vias 222-1 of the conductive routing PH11 in the substrate redistribution layers 230-1 and 230-2. Therefore, the conductive routing PH11 has improved power integrity and is suitable for power transmission.

Beside the advantages of the semiconductor structure 500A, the conductive material 304 in the hole TH1 of the semiconductor structure 500B has lower impedance and resistance than the conductive material 204 in the hole TH1 of semiconductor structure 500B in a condition that the holes TH1 of the semiconductor structures 500A and 500B have the same size. Therefore, the semiconductor structure 500B may have superior power integrity and signal integrity.

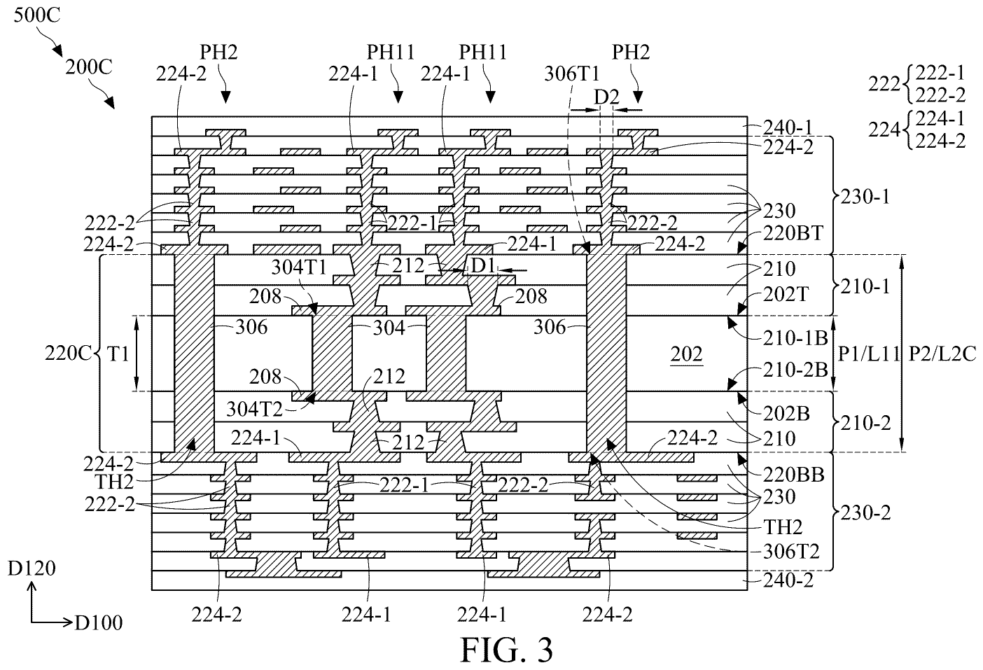

FIG. 3 is a schematic cross-sectional view of a semiconductor structure 500C in accordance with some embodiments of the disclosure. Elements of the embodiments hereinafter, that are the same or similar as those previously described with reference to FIGS. 1 and 2, are not repeated for brevity.

As shown in FIGS. 2 and 3, the difference between the semiconductor structure 500B and the semiconductor structure 500C at least includes that a substrate 200C of the semiconductor structure 500C uses a conductive material 306 to replace the conductive material 206 and the non-conductive material 205-2. The conductive material 306 is formed as a conductive solid pillar filled in the hole TH2 of the core structure 220B. The conductive material 306 also called through hole conductive components 306.

The conductive material 306 in the hole TH2 may have a solid pillar shape. The conductive material 306 may also be called a conductive solid pillar 306. Therefore, there is no non-conductive material 205-2 disposed in the hole TH2.

In some embodiments, the terminal 304T1 of the conductive material 304 in the hole TH1 and the terminal 306T1 of the conductive material 306 in the hole TH2 are close to opposite surfaces of any of the dielectric layers 210 of the core redistribution layer 210-1. For example, the terminal 304T1 of the conductive material 304 in the hole TH1 is close to a surface (also an inner surface 210-1B of the core redistribution layer 210-1) of the inner dielectric layer 210 of the core redistribution layer 210-1 that is close to the top surface 202T of the core 202. The terminal 306T1 of the conductive material 306 in the hole TH2 is close to a surface (also the top surface 220BT) of the outer dielectric layer 210 of the core redistribution layer 210-1 that is close to the top surface 220BT of the core structure 220B.

In other words, the terminal 304T1 of the conductive material 304 in the hole TH1 is close to an inner surface (also the inner surface 210-1B of the core redistribution layer 210-1) of one of the dielectric layers 210 of the core redistribution layer 210-1 that is close to the core 202. The terminal 306T1 of the conductive material 306 in the hole TH2 is close to an outer surface (also the top surface 220BT) of the one of the dielectric layers 210 of the core redistribution layer 210-1 that is away from the core 202.

Similarly, the terminal 304T2 of the conductive material 304 in the hole TH1 and the terminal 306T2 of the conductive material 306 in the hole TH2 are close to opposite surfaces of any of the dielectric layers 210 of the core redistribution layer 210-2. For example, the terminal 304T2 of the conductive material 304 in the hole TH1 is close to a surface (also an inner surface 210-2B of the core redistribution layer 210-2) of the inner dielectric layer 210 of the core redistribution layer 210-2 that is close to the bottom surface 202B of the core 202. The terminal 306T2 of the conductive material 306 in the hole TH2 is close to a surface (also the bottom surface 220BB) of the outer dielectric layer 210 of the core redistribution layer 210-2 that is close to the bottom surface 220BB of the core structure 220B.

In other words, the terminal 304T2 of the conductive material 304 in the hole TH1 is close to an inner surface (also the inner surface 210-2B of the core redistribution layer 210-2) of one of the dielectric layers 210 of the core redistribution layer 210-2 that is close to the core 202. The terminal 306T1 of the conductive material 306 in the hole TH2 is close to an outer surface (also the bottom surface 220BB) of the one of the dielectric layers 210 of the core redistribution layer 210-1 that is away from the core 202.

In some embodiments, in the direction D120, a dimension L11 of the conductive material 304 is substantially equal to the thickness of the core 202. In addition, a dimension L2C of the conductive material 306 is substantially equal to the total thickness of the core 202, and the core redistribution layers 210-1 and 210-2. Therefore, the dimension L11 of the conductive material 304 is smaller than the dimension L2C of the conductive material 306.

In some embodiments, the conductive materials 204, 304 and 306 are formed of the same or similar materials and fabricated in the same or similar process.

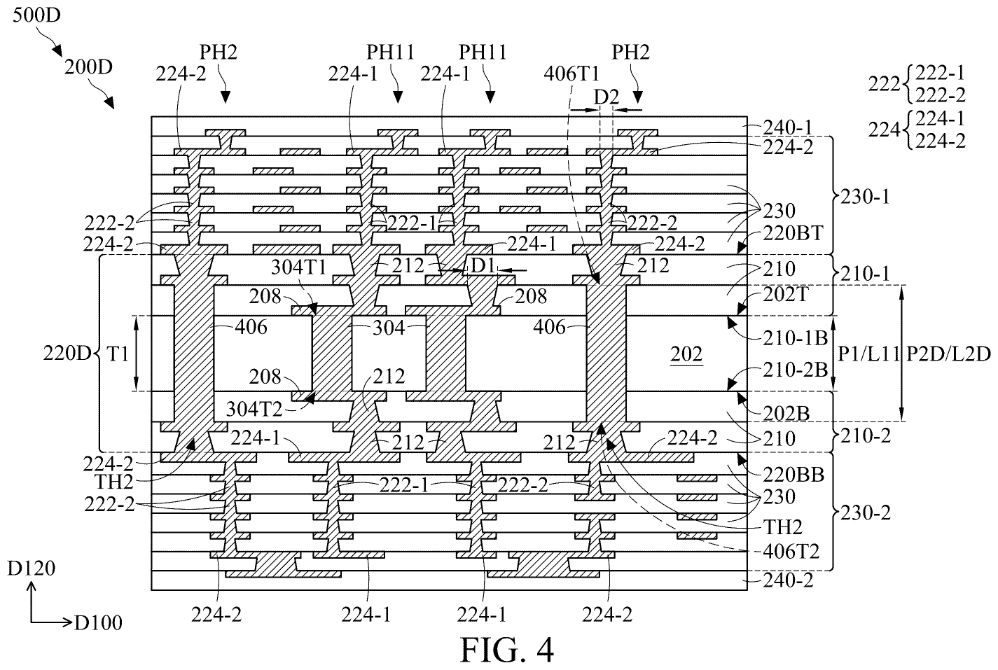

FIG. 4 is a schematic cross-sectional view of a semiconductor structure 500D in accordance with some embodiments of the disclosure. Elements of the embodiments hereinafter, that are the same or similar as those previously described with reference to FIGS. 1 to 3, are not repeated for brevity.

As shown in FIGS. 3 and 4, the difference between the semiconductor structure 500C and the semiconductor structure 500D at least includes that the semiconductor structure 500D at least includes that a hole TH2 of the core structure 220D of a substrate 200D of the semiconductor structure 500D is formed through the inner dielectric layers 210 of the core redistribution layers 210-1 and 210-2 (i.e., portions of the core redistribution layers 210-1 and 210-2).

In some embodiments, the depth P2D of the hole TH2 is substantially equal to the total thickness of the core 202 and the inner core redistribution layers 210-1 and 210-2. The depth P1 of the hole TH1 is smaller than the depth P2 of the hole TH2.

In some embodiments, the substrate 200D of the semiconductor structure 500D includes a conductive material 406 formed as a conductive solid pillar filled in the hole TH2. The conductive material 406 also called through hole conductive components 406.

The conductive material 406 in the hole TH2 may have a solid pillar shape. The conductive material 406 may also be called a conductive solid pillar 306. Therefore, there is no non-conductive material 205-2 disposed in the hole TH2.

In addition, a dimension L2D of the conductive material 306 is substantially equal to the total thickness of the core 202 and the inner core redistribution layers 210-1 and 210-2.

The semiconductor structure 500D further include the vias 212 disposed in the outer dielectric layers 210 of the core redistribution layers 210-1 and 210-2 directly above and below the terminals 406T1 and 406T2 of the conductive material 406. The aforementioned vias 212 are coupled between the conductive material 406 and the conductive layer 224-2.

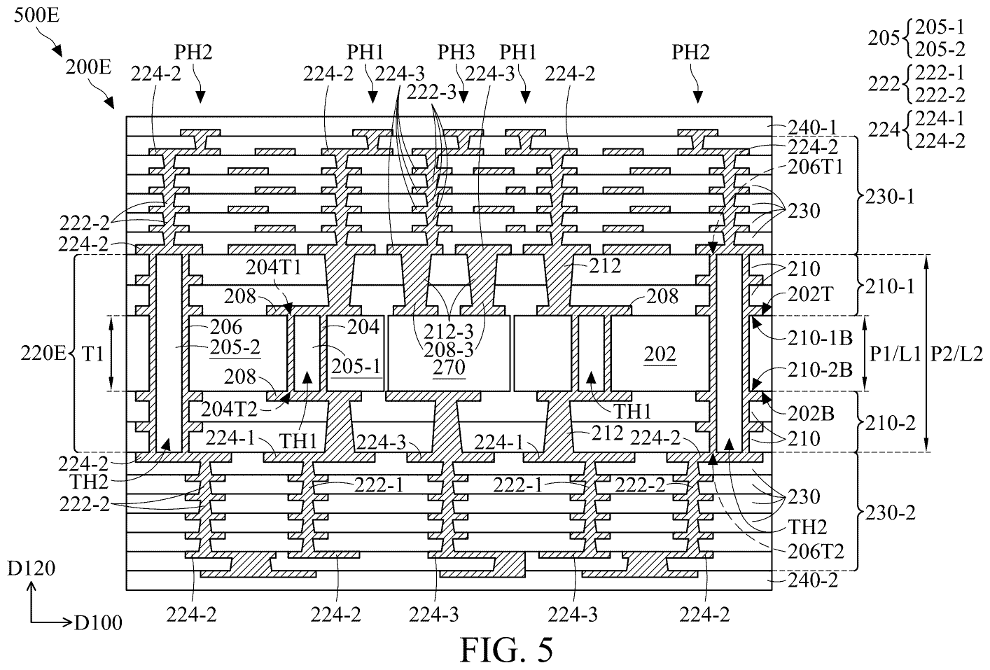

FIG. 5 is a schematic cross-sectional view of a semiconductor structure 500E in accordance with some embodiments of the disclosure. Elements of the embodiments hereinafter, that are the same or similar as those previously described with reference to FIG. 1, are not repeated for brevity.

As shown in FIGS. 1 and 5, the difference between the semiconductor structure 500A and the semiconductor structure 500E at least includes that a substrate 200E of the semiconductor structure 500E further includes at least one integrated passive device (IPD) 270 embedded in the core 202 of the core structure 220C. In addition, the integrated passive device 270 may be coupled to vias 212-3 and conductive layers 208-3 of the core redistribution layer 210-1 and vias 222-3 and the conductive layers 224-3 of the substrate redistribution layer 230-1.

As shown in FIG. 5, the integrated passive device 270 is disposed embedded in the core 202 of the core structure 220C of the substrate 200E. For example, the integrated passive device 270 is disposed in a cavity (not shown) of the core 202. In addition, pads (not shown) of the integrated passive device 270 may be exposed form the top surface 202T or the bottom surface 202B of the core 202. In this embodiment, the pads (not shown) of the integrated passive device 270 may be exposed form the top surface 202T of the core 202. Furthermore, the dielectric layer 210 may fill the remaining space between sidewalls (not shown) of the integrated passive device 270 and the core 202 (e.g., the sidewalls of the cavity) for the isolation between the integrated passive device 270 and the core 202.

In some embodiments, the integrated passive device 270 is coupled to the vias and the conductive layers of the core redistribution layer 210-1 (or the core redistribution layer 210-2) and the substrate redistribution layer 230-1 (or the substrate redistribution layer 230-2) face (close to) the pads of the conductive layers 270. For example, when the pads (not shown) of the integrated passive device 270 may be exposed form the top surface 202T of the core 202, the pads of the conductive layers 270 are coupled to the vias 212-3 and the conductive layers 208-3 disposed in the dielectric layers 210 of the core redistribution layer 210-1 and the vias 222-3 and the conductive layers 224-3 disposed in the dielectric layers 230 of the substrate redistribution layer 230-1. The vias 212-3 and the conductive layers 208-3 of the core redistribution layer 210-1 and the vias 222-3 and the conductive layers 224-3 of the substrate redistribution layer 230-1 are disposed on (and close to) the top surface 202T of the core 202. In this embodiment, the 212-3 may pass through the two dielectric layers 210 of the core redistribution layer 210-1. The vias 212 may pass through the dielectric layers 210 of the core redistribution layers 210-1 and 210-2.

Alternatively, when the pads (not shown) of the integrated passive device 270 may be exposed form the bottom surface 202B of the core 202, the pads of the conductive layers 270 are coupled to vias (not shown) and conductive layers (not shown) disposed in the dielectric layers 210 of the core redistribution layer 210-2 and vias (not shown) and conductive layers (not shown) disposed in the dielectric layers 230 of the substrate redistribution layer 230-2. The aforementioned vias and the conductive layers of the core redistribution layer 210-2 and the substrate redistribution layer 230-2 are disposed on (and close to) the bottom surface 202B of the core 202.

In this embodiment, the conductive traces of the conductive layer 208-3 and the vias 212-3 of the core redistribution layers 210-1, and the conductive traces of the conductive layer 224-3 and the vias 222-3 of the substrate redistribution layers 230-1 may form a conductive routing PH3 (also called the power routing PH3) coupled to the conductive routing PH1 or the conductive routing PH2.

In some embodiments, the integrated passive device 270 includes resistor, inductor, capacitor (e.g., a deep trench capacitor (DTC)), or a combination thereof.

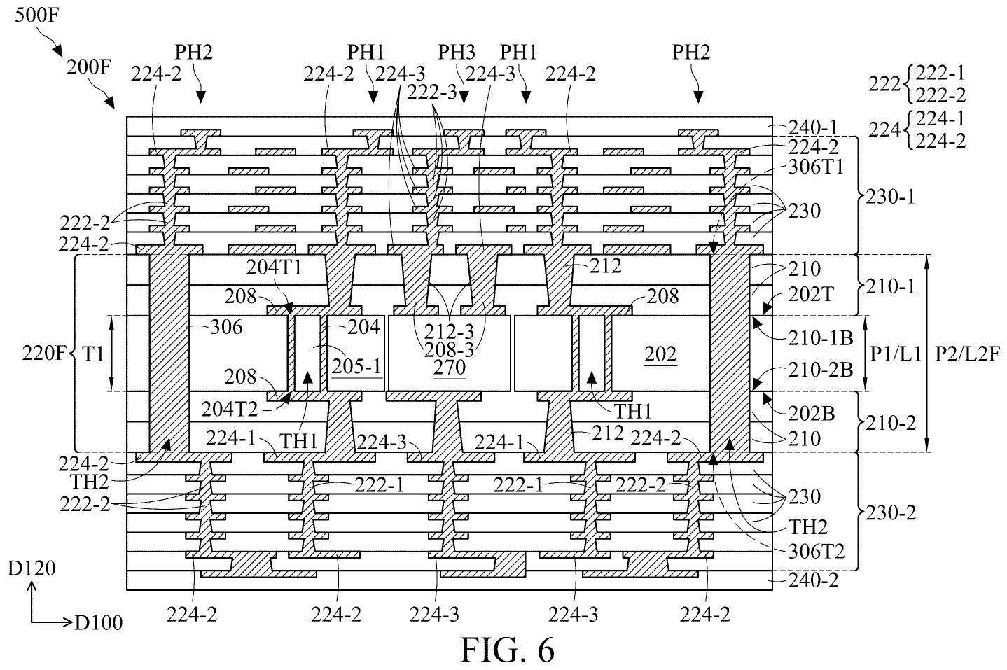

FIG. 6 is a schematic cross-sectional view of a semiconductor structure 500F in accordance with some embodiments of the disclosure. Elements of the embodiments hereinafter, that are the same or similar as those previously described with reference to FIGS. 1 to 5, are not repeated for brevity.

As shown in FIGS. 5 and 6, the difference between the semiconductor structure 500E and the semiconductor structure 500F at least includes that a substrate 200F of the semiconductor structure 500F uses a conductive material 306 to replace the conductive material 206 and the non-conductive material 205-2. The conductive material 306 is formed as a conductive solid pillar filled in the hole TH2 of the core structure 220F. The conductive material 306 also called through hole conductive components 306.

The conductive material 306 in the hole TH2 may have a solid pillar shape. The conductive material 306 may also be called a conductive solid pillar 306. Therefore, there is no non-conductive material 205-2 disposed in the hole TH2.

In this embodiment, the position of the conductive material 306 of the semiconductor structure 500F and the electrical connections among the conductive material 306, the core redistribution layers 210-1, 201-2 and the substrate redistribution layers 230-1, 230-2 may refer to the conductive material 306 of the semiconductor structure 500C and are not repeated for brevity.

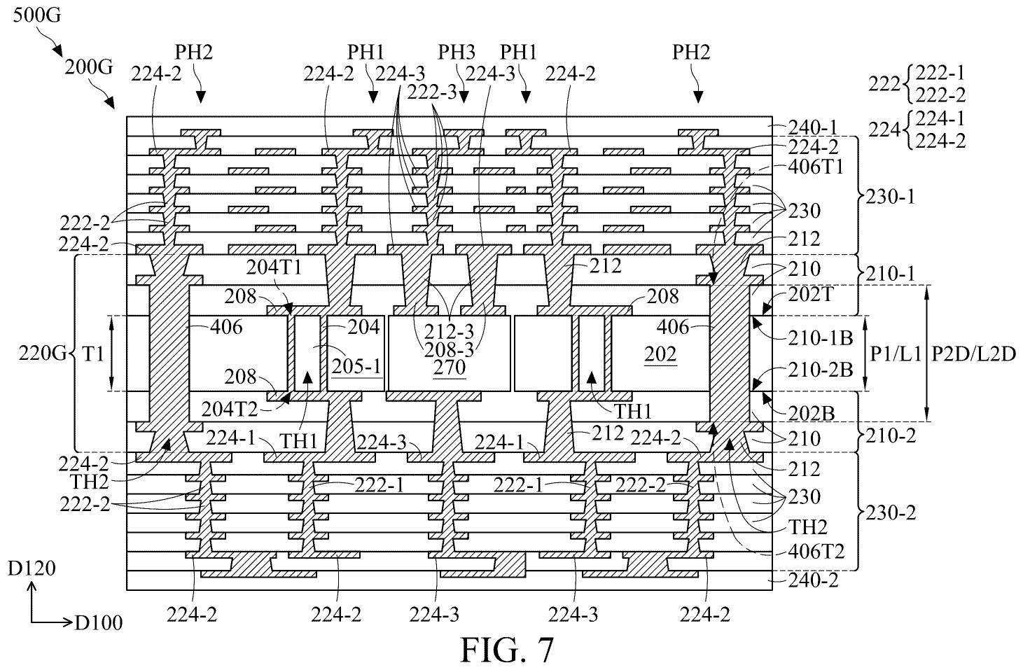

FIG. 7 is a schematic cross-sectional view of a semiconductor structure 500G in accordance with some embodiments of the disclosure. Elements of the embodiments hereinafter, that are the same or similar as those previously described with reference to FIGS. 1 to 6, are not repeated for brevity.

As shown in FIGS. 6 and 7, the difference between the semiconductor structure 500F and the semiconductor structure 500G at least includes that a hole TH2 of the core structure 220G of a substrate 200G of the semiconductor structure 500G is formed through the inner dielectric layers 210 of the core redistribution layers 210-1 and 210-2 (i.e., portions of the core redistribution layers 210-1 and 210-2).

In some embodiments, the depth P2D of the hole TH2 is substantially equal to the total thickness of the core 202 and the inner core redistribution layers 210-1 and 210-2. The depth P1 of the hole TH1 is smaller than the depth P2 of the hole TH2.

In some embodiments, the substrate 200G of the semiconductor structure 500G includes a conductive material 406 formed as a conductive solid pillar filled in the hole TH2. The conductive material 406 also called through hole conductive components 406.

The conductive material 406 in the hole TH2 may have a solid pillar shape. The conductive material 406 may also be called a conductive solid pillar 306. Therefore, there is no non-conductive material 205-2 disposed in the hole TH2.

In this embodiment, the position of the conductive material 406 of the semiconductor structure 500G and the electrical connections among the conductive material 306, the core redistribution layers 210-1, 201-2 and the substrate redistribution layers 230-1, 230-2 may refer to the conductive material 306 of the semiconductor structure 500D and are not repeated for brevity.

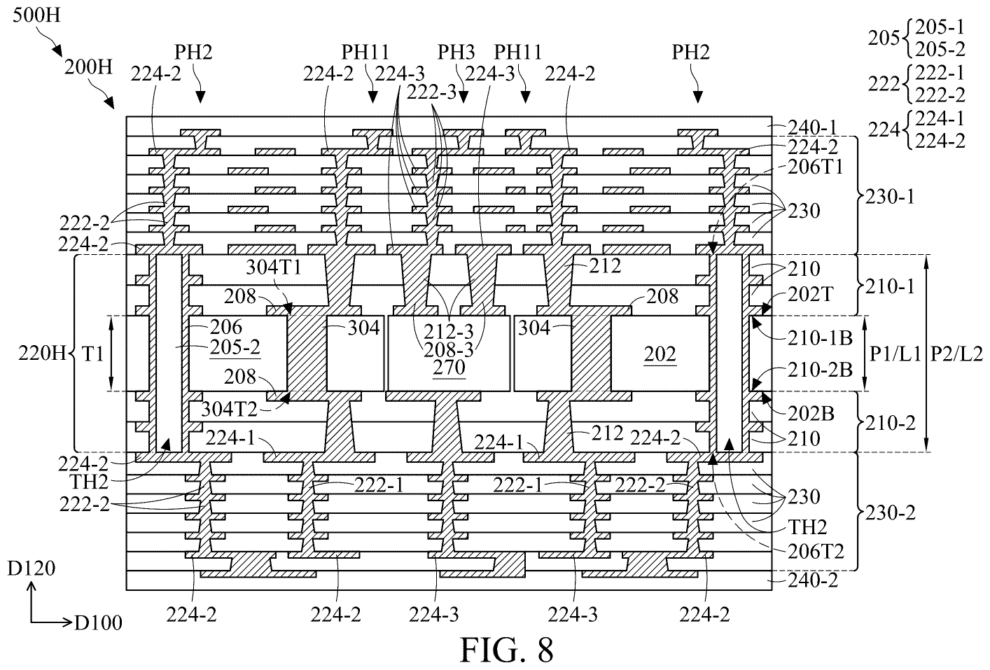

FIG. 8 is a schematic cross-sectional view of a semiconductor structure 500H in accordance with some embodiments of the disclosure. Elements of the embodiments hereinafter, that are the same or similar as those previously described with reference to FIGS. 1 to 7, are not repeated for brevity.

As shown in FIGS. 5 and 8, the difference between the semiconductor structure 500F and the semiconductor structure 500H at least includes that a substrate 200H of the semiconductor structure 500H uses a conductive material 304 to replace the conductive material 204 and the non-conductive material 205-1. The conductive material 304 is formed as a conductive solid pillar filled in the hole TH1 of a core structure 220H. The conductive material 304 also called through hole conductive components 304.

In this embodiment, the position of the conductive material 304 of the semiconductor structure 500H and the electrical connections among the conductive material 306, the core redistribution layers 210-1, 201-2 and the substrate redistribution layers 230-1, 230-2 may refer to the conductive material 304 of the semiconductor structure 500B and are not repeated for brevity.

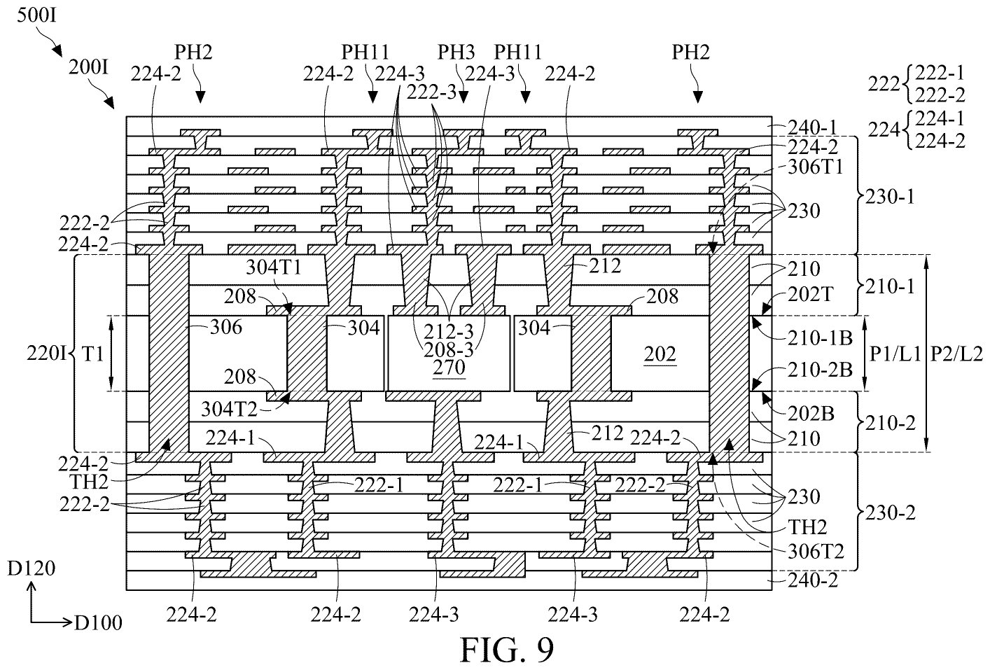

FIG. 9 is a schematic cross-sectional view of a semiconductor structure 500I in accordance with some embodiments of the disclosure. Elements of the embodiments hereinafter, that are the same or similar as those previously described with reference to FIGS. 1 to 8, are not repeated for brevity.

As shown in FIGS. 8 and 9, the difference between the semiconductor structure 500H and the semiconductor structure 500I at least includes that a substrate 200I of the semiconductor structure 500I uses a conductive material 306 to replace the conductive material 206 and the non-conductive material 205-2. The conductive material 306 is formed as a conductive solid pillar filled in the hole TH2 of the core structure 220I. The conductive material 306 also called through hole conductive components 306.

The conductive material 306 in the hole TH2 may have a solid pillar shape. The conductive material 306 may also be called a conductive solid pillar 306. Therefore, there is no non-conductive material 205-2 disposed in the hole TH2.

In this embodiment, the position of the conductive material 306 of the semiconductor structure 500I and the electrical connections among the conductive material 306, the core redistribution layers 210-1, 201-2 and the substrate redistribution layers 230-1, 230-2 may refer to the conductive material 306 of the semiconductor structure 500C and are not repeated for brevity.

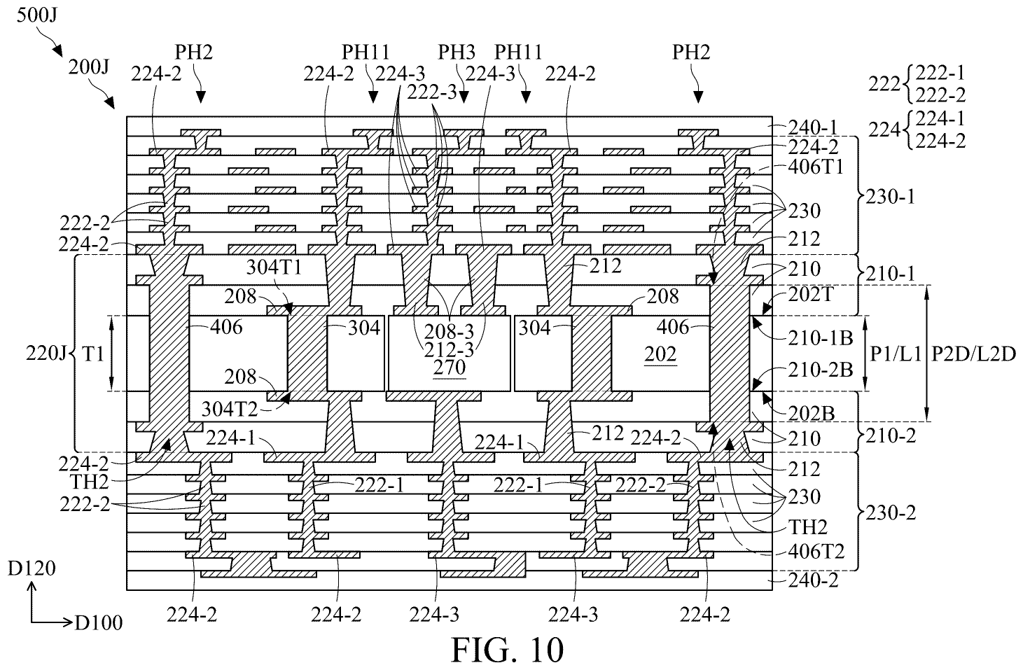

FIG. 10 is a schematic cross-sectional view of a semiconductor structure 500J in accordance with some embodiments of the disclosure. Elements of the embodiments hereinafter, that are the same or similar as those previously described with reference to FIGS. 1 to 9, are not repeated for brevity.

As shown in FIGS. 9 and 10, the difference between the semiconductor structure 500I and the semiconductor structure 500J at least includes that a hole TH2 of the core structure 220J of a substrate 200J of the semiconductor structure 500J is formed through the inner dielectric layers 210 of the core redistribution layers 210-1 and 210-2 (i.e., portions of the core redistribution layers 210-1 and 210-2).

In some embodiments, the depth P2D of the hole TH2 is substantially equal to the total thickness of the core 202 and the inner core redistribution layers 210-1 and 210-2. The depth P1 of the hole TH1 is smaller than the depth P2 of the hole TH2.

In some embodiments, the substrate 200J of the semiconductor structure 500J includes a conductive material 406 formed as a conductive solid pillar filled in the hole TH2. The conductive material 406 also called through hole conductive components 406.

The conductive material 406 in the hole TH2 may have a solid pillar shape. The conductive material 406 may also be called a conductive solid pillar 306. Therefore, there is no non-conductive material 205-2 disposed in the hole TH2.

In this embodiment, the position of the conductive material 406 of the semiconductor structure 500J and the electrical connections among the conductive material 306, the core redistribution layers 210-1, 201-2 and the substrate redistribution layers 230-1, 230-2 may refer to the conductive material 306 of the semiconductor structure 500D and are not repeated for brevity.

Beside the advantages of the semiconductor structures 500A to 500D, the semiconductor structures 500E to 500J including the integrated passive devices 270 embedded in the core 202 further have advantages of small area and/or size, simplify semiconductor bonding technology (SBT) manufacturing processes, increased functionality, improved electrical performance and reliability.

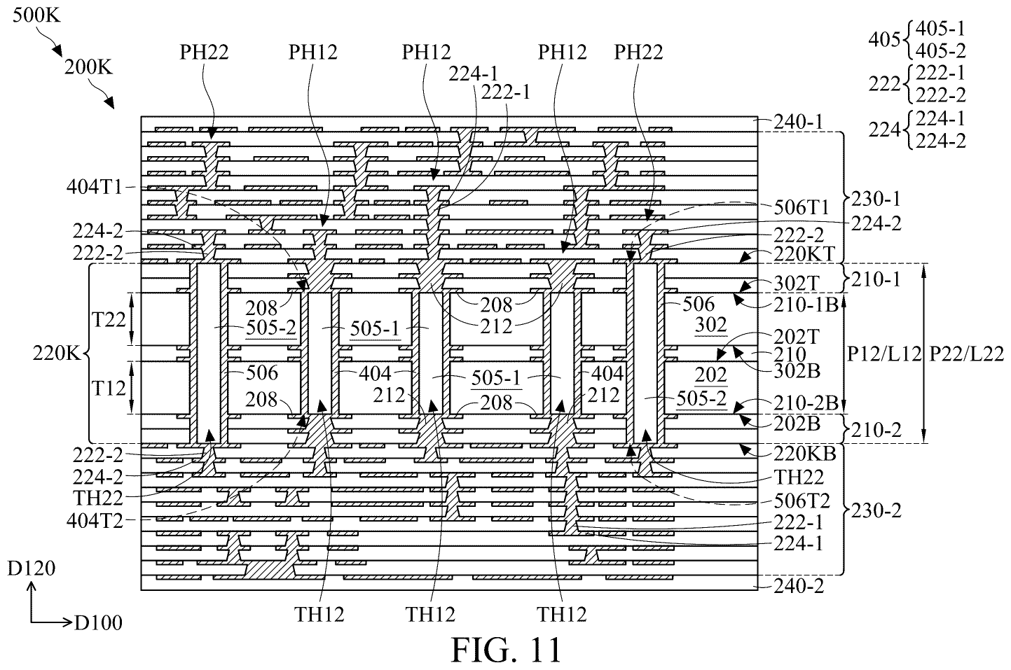

In some embodiments, as shown in FIGS. 11 to 15, the core structure of the substrate of the semiconductor structure is a multi-core structure including at least two cores stacked on each other and separated from each other by one or more dielectric layers formed of prepreg (PP).

FIG. 11 is a schematic cross-sectional view of a semiconductor structure 500K in accordance with some embodiments of the disclosure. Elements of the embodiments hereinafter, that are the same or similar as those previously described with reference to FIGS. 1 to 10, are not repeated for brevity.

As shown in FIGS. 1 and 11, the difference between the semiconductor structure 500A and the semiconductor structure 500K at least includes that a core structure 220K of a substrate 200K of the semiconductor structure 500K includes two cores 202, 302, core redistribution layers 210-1 and 210-2 and an additional dielectric layer 210 between the core redistribution layers 210-1 and 210-2. The substrate 200K may also be called a multi-layer duo core substrate.

As shown in FIG. 11, the core 302 is disposed on the core 202. In this embodiment, the additional dielectric layer 210 is disposed on the top surface 202T of the core 202 and between the top surface 202T of the core 202 and the bottom surface 302B of the core 302. In addition, each of the dielectric layers 210 of the core redistribution layer 210-1 is disposed on the top surface 302T the core 302 and opposite to the additional dielectric layer 210. It is noted that there is no via and/or conductive trace (not shown) positioned in the additional dielectric layer 210.

In the core structure 220K, the thickness T12 of the core 202 may be the same as, larger than or smaller than the thickness T22 of the core 302. In this embodiment, the total thickness (i.e., T12+T22) of the cores 202 and 302 of the core structure 220K may be the same as, larger than or smaller than the thickness T1 of the core 202 of the core structure 220 (FIG. 1), according to the designs. In some embodiments, the cores 202 and 302 may be formed of the same or similar materials.

As shown in FIG. 11, the core structure 220K of the substrate 200K has separated holes TH12 and TH22 embedded it. In this embodiment, the hole TH12 passes through the cores 202 and 302 and the additional dielectric layer 210 between the cores 202 and 302. In addition, the hole TH22 passes through the core structure 220K including the cores 202 and 302 and all of the dielectric layers 210. In some embodiments, in the direction D120, the depth P12 of the hole TH12 is substantially equal to the total thickness of the cores 202, 302 and the additional dielectric layer 210 between the cores 202 and 302. In addition, the depth P22 of the hole TH22 is substantially equal to the total thickness of the cores 202 and 302, the additional dielectric layer 210 between the cores 202 and 302, and the core redistribution layers 210-1 and 210-2. Therefore, the depth of the hole TH12 is smaller than the depth of the hole TH22.

In other words, the core structure 220K of the substrate 200K includes at least two cores 202, 302 and at least three dielectric layers 210 stacked on each other. In addition, the two cores 202, 302 are arranged in such a way that they alternate with the three dielectric layers 210. In some embodiments, the core structure 220K has a hole TH12 passing through the two cores 202, 302 and one of the three dielectric layers 210. In addition, the core structure 220K has a hole TH22 passing through the two cores 202, 302 and the three dielectric layers 210.

The conductive material 404 is disposed in the hole TH12, and the conductive material 506 is disposed in the hole TH22. In some embodiments, as shown in FIG. 11, the conductive material 404 and 506 may have a hollow pillar shape. For example, the conductive materials 404 and 506 may also be called through hole conductive components (e.g., plated through holes (PTHs) 404 and 506.

In this embodiment, two terminals 404T1, 404T2 of the conductive material 404 in the hole TH12 are not aligned with two corresponding terminals 506T1, 506T2 of the conductive material 506 in the hole TH22 in the direction D100. For example, the two terminals 404T1, 404T2 of the conductive material 404 in the hole TH12 may be close to the top surface 302T of the core 302 and the bottom surface 202B of the core 202, respectively. In addition, the two terminals 404T1, 404T2 of the conductive material 404 in the hole TH12 may be exposed from the top surface 302T of the core 302 and the bottom surface 202B of the core 202, respectively. In some embodiments, the two terminals 506T1, 506T2 of the conductive material 506 in the hole TH22 may be close to the top surface 220KT and the bottom surface 220KB of the core structure 220K, respectively. In addition, the two terminals 506T1, 506T2 of the conductive material 506 in the hole TH22 may be exposed from the top surface 220KT and the bottom surface 220KB of the core structure 220K, respectively.

In some embodiments, the terminal 404T1 of the conductive material 404 in the hole TH12 and the terminal 506T1 of the conductive material 506 in the hole TH22 are close to opposite surfaces of any of the dielectric layers 210 of the core redistribution layer 210-1. For example, the terminal 404T1 of the conductive material 404 in the hole TH12 is close to a surface (also an inner surface 210-1B of the core redistribution layer 210-1) of the inner dielectric layer 210 of the core redistribution layer 210-1 that is close to the top surface 302T of the core 302. The terminal 506T1 of the conductive material 506 in the hole TH22 is close to a surface (also the top surface 220KT) of the dielectric layer 210 of the core redistribution layer 210-1 that is close to the top surface 220KT of the core structure 220K.

In other words, the terminal 404T1 of the conductive material 404 in the hole TH12 is close to an inner surface (also the inner surface 210-1B of the core redistribution layer 210-1) of one of the dielectric layers 210 of the core redistribution layer 210-1 that is close to the core 302. The terminal 506T1 of the conductive material 506 in the hole TH22 is close to an outer surface (also the top surface 220KT) of the one of the dielectric layers 210 of the core redistribution layer 210-1 that is away from the core 302.

Similarly, the terminal 404T2 of the conductive material 404 in the hole TH12 and the terminal 506T2 of the conductive material 506 in the hole TH22 are close to opposite surfaces of any of the dielectric layers 210 of the core redistribution layer 210-2. For example, the terminal 404T2 of the conductive material 404 in the hole TH12 is close to a surface (also an inner surface 210-2B of the core redistribution layer 210-2) of the inner dielectric layer 210 of the core redistribution layer 210-2 that is close to the bottom surface 202B of the core 202. The terminal 506T2 of the conductive material 506 in the hole TH22 is close to a surface (also the bottom surface 220KB) of the dielectric layer 210 of the core redistribution layer 210-2 that is close to the bottom surface 220KB of the core structure 220K.

In other words, the terminal 404T2 of the conductive material 404 in the hole TH12 is close to an inner surface (also the inner surface 210-2B of the core redistribution layer 210-2) of one of the dielectric layers 210 of the core redistribution layer 210-2 that is close to the core 202. The terminal 506T1 of the conductive material 506 in the hole TH22 is close to an outer surface (also the bottom surface 220KB) of the one of the dielectric layers 210 of the core redistribution layer 210-1 that is away from the core 202.

In some embodiments, in the direction D120, a dimension L12 of the conductive material 404 is substantially equal to the total thickness of the cores 202, 302 and the additional dielectric layer 210 between the cores 202 and 302. In addition, a dimension L22 of the conductive material 506 is substantially equal to the total thickness of the cores 202, 302, the additional dielectric layer 210 between the cores 202 and 302, and the core redistribution layers 210-1 and 210-2. Therefore, the dimension L12 of the conductive material 404 is smaller than the dimension L22 of the conductive material 506.

In some embodiments, the conductive materials 204, 206, 404 and 506 are formed of the same or similar materials and fabricated in the same or similar process.

As shown in FIG. 11, the semiconductor structure 500K further includes a non-conductive material 505 (including non-conductive material portions 505-1, 505505-2) filling the remaining spaces of the holes TH12 and TH22 and surrounded by the conductive materials 404, 506. For example, the non-conductive material portion 505-1 may fill the hole TH12 and be surrounded by the conductive material 404. In addition, the non-conductive material portion 505505-2 may fill the hole TH22 and be surrounded by the conductive material portion 506. In some embodiments, the non-conductive material 205 and 505 may have the same or similar materials and processes.

In other words, at least two dielectric layers 230 of the semiconductor structure 500K are disposed on the top surface 220KT and the bottom surface 220KB of the core structure 220K and connected to the top dielectric layer 210 and the bottom dielectric layer 210. The three first dielectric layers 210 and the two dielectric layers 230 are made of different materials.

In this embodiment, the electrical connections among the conductive material 404, the core redistribution layers 210-1, 210-2 and the substrate redistribution layer 230-1, 230-2 may refer to the electrical connections among the conductive material 204, the core redistribution layers 210-1, 210-2 and the substrate redistribution layer 230-1, 230-2 of the semiconductor structure 500A and are not repeated for brevity. In this embodiment, the electrical connections among the conductive material 506 and the substrate redistribution layer 230-1, 230-2 may refer to the electrical connections among the conductive material 206 and the substrate redistribution layer 230-1, 230-2 of the semiconductor structure 500A and are not repeated for brevity.

In some embodiments, the substrate 200K of the semiconductor structure 500K provides various types of conductive lines for power transmission and signal transmission. In some embodiments, the conductive material 404 in the hole TH12 passing through the core of the core structure 220K, the conductive traces of the conductive layer 208 and the vias 212 of the core redistribution layers 210-1 and 210-2, and the conductive traces of the conductive layer 224-1 and the vias 222-1 of the substrate redistribution layers 230-1 and 230-2 may form a conductive routing PH12 (also called the power routing PH12) for power transmission. For example, the power routing PH12 may include positive power supply voltage VDD, ground power supply voltage VSS, overdriven voltage signals (e.g., signals greater than VDD), negative power supply voltage signals, and other power supply voltage signals. In some embodiments, corresponding to the material and process characteristics of the dielectric layers 210 and 230, the routing density of the conductive routing PH12 in the core redistribution layers 210-1 and 210-2 is lower than that of the conductive routing PH12 in the substrate redistribution layers 230-1 and 230-2. For example, the conductive traces of the conductive layer 208 of the core redistribution layers 210-1 and 210-2 have the wider minimum line width and larger spacing than the conductive traces of the conductive layer 224-1 of the conductive routing PH12 in the substrate redistribution layers 230-1 and 230-2. Moreover, the diameter D1 of the vias 212 of the conductive routing PH12 in the core redistribution layers 210-1 and 210-2 is larger than the diameter D2 of the vias 222-1 of the conductive routing PH12 in the substrate redistribution layers 230-1 and 230-2. Therefore, the conductive routing PH12 has improved power integrity and is suitable for power transmission.

In addition, the conductive material 506 in the hole TH22 passing through the core structure 220K, and the conductive traces of the conductive layer 224-2 and the vias 222-2 of the substrate redistribution layers 230-1 and 230-2 may form a conductive routing PH22 for signal transmission (also called the signal routing PH22). Since the conductive material 506 is formed in the hole TH22 passing through the core 202 and the whole dielectric layers 210 of the core redistribution layers 210-1 and 210-2, the conductive routing PH22 may have fewer interfaces between vias and connected conductive traces of the redistribution layers (e.g., the conductive routing PH22 may be formed without the conductive traces of the conductive layer 208 and the vias 212 of the core redistribution layers 210-1 and 210-2). Therefore, the conductive routing PH22 has improved signal integrity and is suitable for signal transmission.

Since the core structure 220K is a composite structure composed of the cores 202, 302 and the dielectric layer 210 disposed on opposite surfaces of the cores 202, 302. Moreover, the dielectric layer 210 are formed of prepreg (PP). The mechanical strength of the substrate 200K is improved. In addition, the conductive material 404 passing through the cores 202, 302 only and the conductive material 506 passing through the core structure 220K may form the conductive routings PH12 and PH22 suitable for power transmission and signal transmission. Therefore, the semiconductor structure 500K can balance between power integrity and signal integrity.

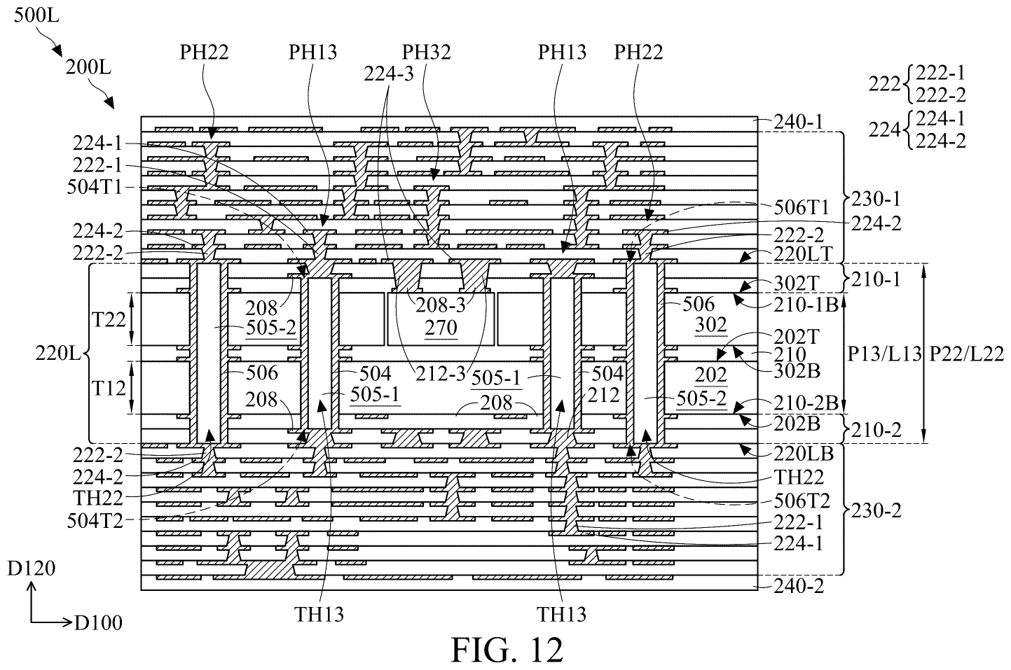

FIG. 12 is a schematic cross-sectional view of a semiconductor structure 500L in accordance with some embodiments of the disclosure. Elements of the embodiments hereinafter, that are the same or similar as those previously described with reference to FIGS. 1, 5 and 11, are not repeated for brevity.

As shown in FIGS. 5 and 6, the difference between the semiconductor structure 500E and the semiconductor structure 500L at least includes that a substrate 200L of the semiconductor structure 500L further includes an integrated passive device (IPD) 270 embedded in the core 302 of the core structure 220L. In addition, the core redistribution layer 210-1 may further include vias 212-3 and conductive layers 208-3, and the substrate redistribution layer 230-1 may further include vias (not shown) and the conductive layers 224-3 to be coupled to the integrated passive device 270. In addition, a conductive material (through hole conductive component) 504 of the substrate 200L is disposed in a hole TH13 passing through the cores 202 and 302 and the three dielectric layers 210 on opposite surfaces of the cores 202 and 302.

As shown in FIG. 12, the core structure 220L of the substrate 200L further include the hole TH13 passing through the cores 202 and 302 the additional dielectric layer 210 between the cores 202 and 302 and the innermost dielectric layers 210 of the core redistribution layer 210-1 and 210-2. In some embodiments, in the direction D120, the depth P13 of the hole TH13 is substantially equal to the total thickness of the cores 202, 302, the additional dielectric layer 210 between the cores 202 and 302 and the innermost dielectric layers 210 of the core redistribution layer 210-1 and 210-2. The depth of the hole TH13 is smaller than the depth of the hole TH22.

In other words, the core structure 220L of the substrate 200L includes at least two cores 202, 302 and at least five dielectric layers 210 stacked on each other. In addition, the cores 202, 302 are arranged in such a way that they alternate with three of the five dielectric layers 210. Moreover, the remaining two dielectric layers 210 are positioned as the top and bottom layers of the core structure 220L. In some embodiments, the core structure 220L has a hole TH13 passing through the cores 202, 302 and the middle three dielectric layers 210. In addition, the core structure 220L has a hole TH22 passing through the cores 202, 302 and the five dielectric layers 210.

The conductive material (through hole conductive component) 504 is disposed in the hole TH13, and the non-conductive material 505-1 fills the remaining spaces of the hole TH13. In some embodiments, as shown in FIG. 12, the conductive material 504 in the hole TH13 may have a hollow pillar shape. For example, the conductive material 504 may also be called a plated through hole (PTH) 504.

In this embodiment, two terminals 504T1, 504T2 of the conductive material 504 in the hole TH13 are not aligned with two corresponding terminals 506T1, 506T2 of the conductive material 506 in the hole TH22 in the direction D100. For example, the two terminals 504T1, 504T2 of the conductive material 504 in the hole TH13 may be close to and exposed from the outer surfaces of the innermost dielectric layers 210 on the top surface 302T of the core 302 and the bottom surface 202B of the core 202, respectively.

In some embodiments, the terminal 504T1 of the conductive material 504 in the hole TH13 and the terminal 506T1 of the conductive material 506 in the hole TH22 are close to opposite surfaces of the outermost dielectric layer 210 of the core redistribution layer 210-1.

In other words, the terminal 504T1 of the conductive material 504 in the hole TH13 is close to an inner surface of the outermost dielectric layer 210 of the core redistribution layer 210-1 that is close to the core 302. The terminal 506T1 of the conductive material 506 in the hole TH22 is close to an outer surface (also the top surface 220LT) of the outermost dielectric layer 210 of the core redistribution layer 210-1 that is away from the core 302.

Similarly, the terminal 504T2 of the conductive material 504 in the hole TH13 and the terminal 506T2 of the conductive material 506 in the hole TH22 are close to opposite surfaces of any of the dielectric layers 210 of the core redistribution layer 210-2. For example, the terminal 504T2 of the conductive material 504 in the hole TH13 is close to a surface of the outermost dielectric layer 210 of the core redistribution layer 210-2 that is close to the bottom surface 202B of the core 202. The terminal 506T2 of the conductive material 506 in the hole TH22 is close to a surface (also the bottom surface 220LB) of the outermost dielectric layer 210 of the core redistribution layer 210-2 that is close to the bottom surface 220LB of the core structure 220L.

In other words, the terminal 504T2 of the conductive material 504 in the hole TH13 is close to an inner surface of the outermost dielectric layers 210 of the core redistribution layer 210-2 that is close to the core 202. The terminal 506T1 of the conductive material 506 in the hole TH22 is close to an outer surface (also the bottom surface 220LB) of the outermost dielectric layers 210 of the core redistribution layer 210-1 that is away from the core 202.

In some embodiments, in the direction D120, a dimension L13 of the conductive material 504 is substantially equal to the total thickness of the cores 202, 302 and the additional dielectric layers 210 on the opposite surfaces of the cores 202 and 302. The dimension L13 of the conductive material 504 is smaller than the dimension L22 of the conductive material 506.

In some embodiments, the conductive materials 204, 206, 404, 506 and 504 may have the same or similar materials and processes. In some embodiments, the non-conductive material 205, 405 and 505-1 may have the same or similar materials and processes.

In some embodiments, the substrate 200L of the semiconductor structure 500L provides various types of conductive lines for power transmission and signal transmission. In some embodiments, the conductive material 504 in the hole TH13, the conductive traces of the conductive layer 208 and the vias 212 of the core redistribution layers 210-1 and 210-2, and the conductive traces of the conductive layer 224-1 and the vias 222-1 of the substrate redistribution layers 230-1 and 230-2 may form a conductive routing PH13 (also called the power routing PH13) for power transmission. In some embodiments, corresponding to the material and process characteristics of the dielectric layers 210 and 230, the routing density of the conductive routing PH13 in the core redistribution layers 210-1 and 210-2 is lower than that of the conductive routing PH13 in the substrate redistribution layers 230-1 and 230-2. Therefore, the conductive routing PH13 has improved power integrity and is suitable for power transmission.

Since the core structure 220L is a composite structure composed of the cores 202, 302 and the dielectric layers 210 disposed on opposite surfaces of the cores 202, 302 and formed of prepreg (PP), the mechanical strength of the substrate 200L is improved. In addition, the conductive material 504 passing through the cores 202, 302 and the middle three dielectric layers 210 only and the conductive material 506 passing through the core structure 220L may form the conductive routings PH13 and PH22 suitable for power transmission and signal transmission. Therefore, the semiconductor structure 500L can balance between power integrity and signal integrity.

In some embodiments, the integrated passive device 270 of the semiconductor structure 500L is disposed embedded in the core close to the top surface 220LT or the bottom surface 220BT of the core structure 220L. As shown in FIG. 12, the integrated passive device 270 is disposed embedded in the core 302 of the core structure 220L of the substrate 200L. The core 302 is close to the top surface 220LT of the core structure 220L. For example, the integrated passive device 270 is disposed in a cavity (not shown) of the core 302. In addition, pads (not shown) of the integrated passive device 270 may be exposed form the top surface 302T of the core 302. In this embodiment, the pads (not shown) of the integrated passive device 270 may be exposed form the top surface 302T of the core 302. Furthermore, the dielectric layer 210 may fill the remaining space between sidewalls (not shown) of the integrated passive device 270 and the core 302 (e.g., the sidewalls of the cavity) for the isolation between the integrated passive device 270 and the core 302.

Alternatively, the integrated passive device 270 may be disposed embedded in the core 202 of the core structure 220L of the substrate 200L. The core 202 is close to the bottom surface 220LB of the core structure 220L. For example, the integrated passive device 270 is disposed in a cavity (not shown) of the core 202. In addition, pads (not shown) of the integrated passive device 270 may be exposed form the bottom surface 202B of the core 202. In this embodiment, the pads (not shown) of the integrated passive device 270 may be exposed form the bottom surface 202B of the core 202. Furthermore, the dielectric layer 210 may fill the remaining space between sidewalls (not shown) of the integrated passive device 270 and the core 202 (e.g., the sidewalls of the cavity) for the isolation between the integrated passive device 270 and the core 202.

In some embodiments, the integrated passive device 270 is coupled to the vias and the conductive layers of the core redistribution layer 210-1 (or the core redistribution layer 210-2) and the substrate redistribution layer 230-1 (or the substrate redistribution layer 230-2) face (close to) the pads of the conductive layers 270. For example, when the pads (not shown) of the integrated passive device 270 may be exposed form the top surface 302T of the core 302, the pads of the conductive layers 270 are coupled to the vias 212-3 and the conductive layers 208-3 disposed in the dielectric layers 210 of the core redistribution layer 210-1 and the vias (not shown) and the conductive layers 224-3 disposed in the dielectric layers 230 of the substrate redistribution layer 230-1. The vias 212-3 and the conductive layers 208-3 of the core redistribution layer 210-1 and the vias (not shown) and the conductive layers 224-3 of the substrate redistribution layer 230-1 are disposed on (and close to) the top surface 302T of the core 302. In this embodiment, the 212-3 may pass through the two dielectric layers 210 of the core redistribution layer 210-1.

Alternatively, when the pads (not shown) of the integrated passive device 270 may be exposed form the bottom surface 202B of the core 202, the pads of the conductive layers 270 are coupled to vias (not shown) and conductive layers 224-3 disposed in the dielectric layers 210 of the core redistribution layer 210-2 and vias (not shown) and conductive layers 224-3 disposed in the dielectric layers 230 of the substrate redistribution layer 230-2. The vias and the conductive layers of the core redistribution layer 210-2 and the substrate redistribution layer 230-2 are disposed on (and close to) the bottom surface 202B of the core 202.

In this embodiment, the conductive traces of the conductive layer 208-3 and the vias 212-3 of the core redistribution layers 210-1, and the conductive traces of the conductive layer 224-3 and the vias (not shown) of the substrate redistribution layers 230-1 may form a conductive routing PH32 (also called the power routing PH32) coupled to the conductive routing PH13 or the conductive routing PH22.

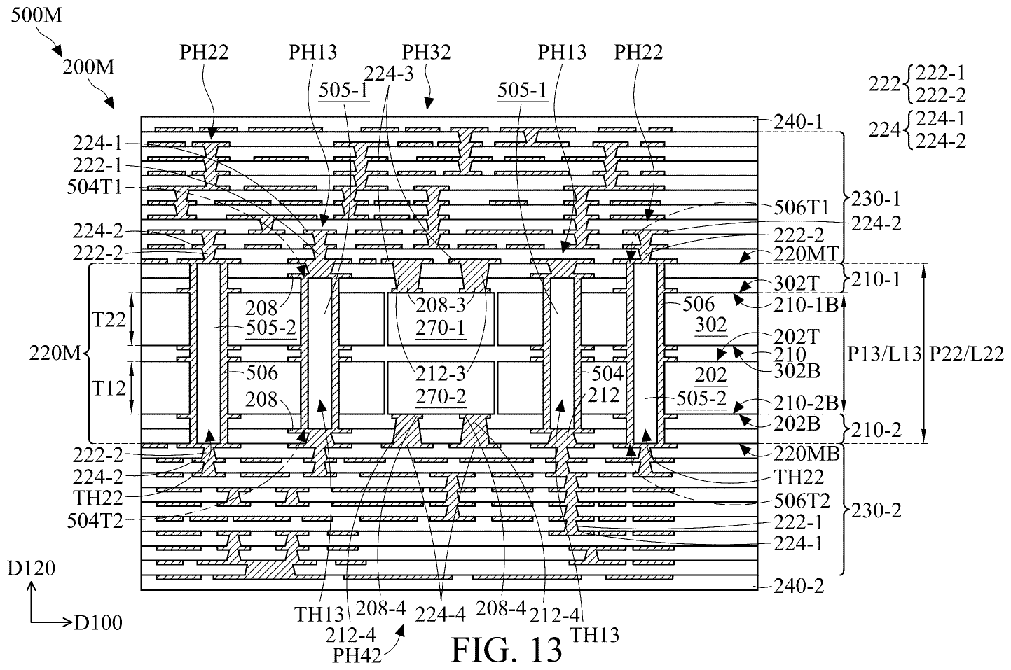

FIG. 13 is a schematic cross-sectional view of a semiconductor structure 500M in accordance with some embodiments of the disclosure. Elements of the embodiments hereinafter, that are the same or similar as those previously described with reference to FIGS. 1, 5, 11 and 12, are not repeated for brevity.

As shown in FIGS. 12 and 13, the difference between the semiconductor structure 500F and the semiconductor structure 500M at least includes that a core structure 220M of a substrate 200M of the semiconductor structure 500M further includes an integrated passive device (IPD) 270-1 embedded in the core 302 and an integrated passive device (IPD) 270-2 embedded in the core 202. In addition, the core redistribution layer 210-1 may further include vias 212-3 and conductive layers 208-3, and the substrate redistribution layer 230-1 may further include vias (not shown) and the conductive layers 224-3 to be coupled to the integrated passive device 270-1. Moreover, the core redistribution layer 210-2 may further include vias 212-4 and conductive layers 208-4, and the substrate redistribution layer 230-2 may further include vias (not shown) and the conductive layers 224-4 to be coupled to the integrated passive device 270-2.

In some embodiments, the integrated passive devices 270-1 and 270-2 of the semiconductor structure 500M are disposed embedded in the cores 202 and 302 close to the top surface 220FT and the bottom surface 220BT of the core structure 220F. The integrated passive devices 270-1 and 270-2 are separated from each other. As shown in FIG. 13, the integrated passive device 270-1 is disposed embedded in the core 302 of the core structure 220F of the substrate 200F. The core 302 is close to the top surface 220FT of the core structure 220F. For example, the integrated passive device 270-1 is disposed in a cavity (not shown) of the core 302. In addition, pads (not shown) of the integrated passive device 270-1 may be exposed form the top surface 302T of the core 302. In this embodiment, the pads (not shown) of the integrated passive device 270-1 may be exposed form the top surface 302T of the core 302. Furthermore, the dielectric layer 210 may fill the remaining space between sidewalls (not shown) of the integrated passive device 270-1 and the core 302 (e.g., the sidewalls of the cavity) for the isolation between the integrated passive device 270-1 and the core 302.

As shown in FIG. 13, the integrated passive device 270-2 may be disposed embedded in the core 202 of the core structure 220M of the substrate 200M. The core 202 is close to the bottom surface 220MB of the core structure 220M. For example, the integrated passive device 270-2 is disposed in a cavity (not shown) of the core 202. In addition, pads (not shown) of the integrated passive device 270-2 may be exposed form the bottom surface 202B of the core 202. In this embodiment, the pads (not shown) of the integrated passive device 270-2 may be exposed form the bottom surface 202B of the core 202. Furthermore, the dielectric layer 210 may fill the remaining space between sidewalls (not shown) of the integrated passive device 270-2 and the core 202 (e.g., the sidewalls of the cavity) for the isolation between the integrated passive device 270-2 and the core 202.

In some embodiments, the integrated passive devices 270-1 and 270-2 are coupled to the vias and the conductive layers of the core redistribution layers 210-1, 210-2 and the substrate redistribution layers 230-1, 230-2 face (close to) the pads of the conductive layers 270-1 and 270-2. As shown in FIG. 13, the pads (not shown) of the conductive layers 270-1 are coupled to the vias 212-3 and the conductive layers 208-3 disposed in the dielectric layers 210 of the core redistribution layer 210-1 and the vias (not shown) and the conductive layers 224-3 disposed in the dielectric layers 230 of the substrate redistribution layer 230-1. The vias 212-3 and the conductive layers 208-3 of the core redistribution layer 210-1 and the vias (not shown) and the conductive layers 224-3 of the substrate redistribution layer 230-1 are disposed on (and close to) the top surface 302T of the core 302.

As shown in FIG. 13, the pads (not shown) of the conductive layers 270-2 are coupled to vias 212-4 and conductive layers 208-4 disposed in the dielectric layers 210 of the core redistribution layer 210-2 and vias (not shown) and conductive layers 224-4 disposed in the dielectric layers 230 of the substrate redistribution layer 230-2. The vias and the conductive layers of the core redistribution layer 210-2 and the substrate redistribution layer 230-2 are disposed on (and close to) the bottom surface 202B of the core 202.

In this embodiment, the conductive traces of the conductive layer 208-3 and the vias 212-3 of the core redistribution layers 210-1, and the conductive traces of the conductive layer 224-3 and the vias (not shown) of the substrate redistribution layers 230-1 may form a conductive routing PH32 (also called the power routing PH32) coupled to the conductive routing PH13 or the conductive routing PH22. In addition, the conductive traces of the conductive layer 208-4 and the vias 212-4 of the core redistribution layers 210-2, and the conductive traces of the conductive layer 224-4 and the vias (not shown) of the substrate redistribution layers 230-2 may form a conductive routing PH42 (also called the power routing PH42) coupled to the conductive routing PH13 or the conductive routing PH22.

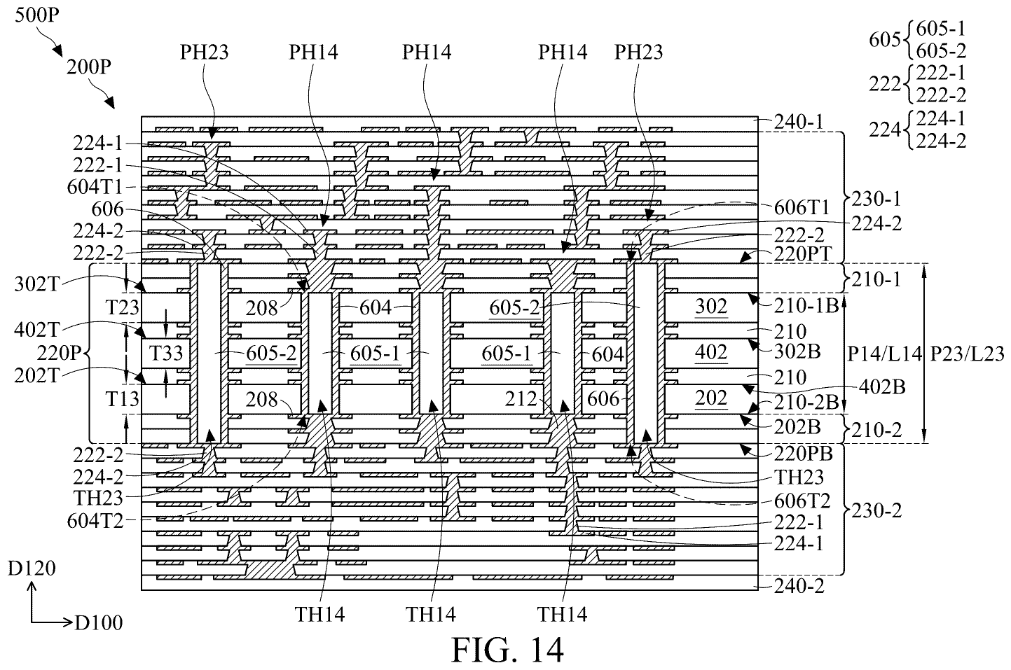

FIG. 14 is a schematic cross-sectional view of a semiconductor structure 500P in accordance with some embodiments of the disclosure. Elements of the embodiments hereinafter, that are the same or similar as those previously described with reference to FIGS. 1 and 11, are not repeated for brevity.

As shown in FIGS. 11 and 14, the difference between the semiconductor structure 500K and the semiconductor structure 500P at least includes that a core structure 220P of a substrate 200P of the semiconductor structure 500P includes three cores 202, 302 and 402, core redistribution layers 210-1 and 210-2 and two additional dielectric layers 210 between the core redistribution layers 210-1 and 210-2. The substrate 200P may also be called a multi-layer triple core (or multi-core) substrate.

As shown in FIG. 14, the core 402 is disposed between the cores 202 and 302 in the direction D120. In this embodiment, one additional dielectric layer 210 is disposed on the top surface 202T of the core 202 and between the top surface 202T of the core 202 and the bottom surface 402B of the core 402. Another additional dielectric layer 210 is disposed on the top surface 402T of the core 402 and between the top surface 402T of the core 402 and the bottom surface 302B of the core 302.

In addition, the inner one of the dielectric layer 210 of the core redistribution layer 210-1 is disposed on the top surface 402T the core 402 and opposite to the two additional dielectric layers 210. The inner one of the dielectric layer 210 of the core redistribution layer 210-2 is disposed on the bottom surface 202B of the core 202 and opposite to the two additional dielectric layers 210. It is noted that there is no via and/or conductive trace (not shown) positioned in the two additional dielectric layers 210.

In the core structure 220E, the thickness T13 of the core 202, the thickness T23 of the core 302 and the thickness T33 of the core 402 may have the same or different values. In this embodiment, the total thickness (i.e., T13+T23+T33) of the cores 202, 302 and 402 of the core structure 220P may be the same as, larger than or smaller than the thickness T1 of the core 202 (single core) of the core structure 220 (FIG. 1), according to the design. In some embodiments, the cores 202, 302 and 402 may be formed of the same or similar materials.

As shown in FIG. 14, the core structure 220P of the substrate 200P has separated holes TH13 and TH23 embedded it. In this embodiment, the hole TH13 passes through the cores 202, 302 and 402 and the additional dielectric layers 210 between the cores 202, 302 and 402. In addition, the hole TH23 passes through the core structure 220P including the cores 202, 302 and 402 and all of the dielectric layers 210. In some embodiments, in the direction D120, the depth P14 of the hole TH13 is substantially equal to the total thickness of the cores 202, 302, 402 and the additional dielectric layers 210 between the cores 202, 302 and 402. In addition, the depth P23 of the hole TH23 is substantially equal to the total thickness of the cores 202, 302 and 402, the additional dielectric layers 210 between the cores 202, 302 and 402, and the core redistribution layers 210-1 and 210-2. Therefore, the depth of the hole TH13 is smaller than the depth of the hole TH23.

In other words, the core structure 220P of the substrate 200P includes at least three cores 202, 302, 402 and at least four dielectric layers 210 stacked on each other. In addition, the three cores 202, 302, 402 are arranged in such a way that they alternate with the four dielectric layers 210. In some embodiments, the core structure 220P has a hole TH13 passing through the three cores 202, 302, 402 and two of the four dielectric layers 210. In addition, the core structure 220P has a hole TH23 passing through the three cores 202, 302, 402 and the four dielectric layers 210.

The substrate 200P further includes a conductive material (through hole conductive component) 604 disposed in the hole TH14, and a conductive material (through hole conductive component) 606 disposed in the hole TH23. In some embodiments, as shown in FIG. 14, the conductive material 604 in the hole TH14 and the conductive material 606 in the hole TH23 may have a hollow pillar shape. For example, the conductive material 604 and 606 may also be called plated through holes (PTHs) 604 and 606.

In this embodiment, two terminals 604T1, 604T2 of the conductive material 604 in the hole TH14 are not aligned with two corresponding terminals 606T1, 606T2 of the conductive material 606 in the hole TH23 in the direction D100. For example, the two terminals 604T1, 604T2 of the conductive material 604 in the hole TH14 may be close to the top surface 302T of the core 302 and the bottom surface 202B of the core 202, respectively. In addition, the two terminals 604T1, 604T2 of the conductive material 604 in the hole TH14 may be exposed from the top surface 302T of the core 302 and the bottom surface 202B of the core 202, respectively. In some embodiments, the two terminals 606T1, 606T2 of the conductive material 606 in the hole TH23 may be close to the top surface 220PT and the bottom surface 220PB of the core structure 220P, respectively. In addition, the two terminals 606T1, 606T2 of the conductive material 606 in the hole TH23 may be exposed from the top surface 220PT and the bottom surface 220PB of the core structure 220P, respectively.

In some embodiments, the terminal 604T1 of the conductive material 604 in the hole TH14 and the terminal 606T1 of the conductive material 606 in the hole TH23 are close to opposite surfaces of any of the dielectric layers 210 of the core redistribution layer 210-1. For example, the terminal 604T1 of the conductive material 604 in the hole TH14 is close to a surface (also an inner surface 210-1B of the core redistribution layer 210-1) of the inner dielectric layer 210 of the core redistribution layer 210-1 that is close to the top surface 302T of the core 302. The terminal 606T1 of the conductive material 606 in the hole TH23 is close to a surface (also the top surface 220PT) of the outer dielectric layer 210 of the core redistribution layer 210-1 that is close to the top surface 220PT of the core structure 220P.

In other words, the terminal 604T1 of the conductive material 604 in the hole TH14 is close to an inner surface (also the inner surface 210-1B of the core redistribution layer 210-1) of one of the dielectric layers 210 of the core redistribution layer 210-1 that is close to the core 302. The terminal 606T1 of the conductive material 606 in the hole TH23 is close to an outer surface (also the top surface 220PT) of the one of the dielectric layers 210 of the core redistribution layer 210-1 that is away from the core 302.

Similarly, the terminal 604T2 of the conductive material 604 in the hole TH14 and the terminal 606T2 of the conductive material 606 in the hole TH23 are close to opposite surfaces of any of the dielectric layers 210 of the core redistribution layer 210-2. For example, the terminal 604T2 of the conductive material 604 in the hole TH14 is close to a surface (also an inner surface 210-2B of the core redistribution layer 210-2) of the inner dielectric layer 210 of the core redistribution layer 210-2 that is close to the bottom surface 202B of the core 202. The terminal 606T2 of the conductive material 606 in the hole TH23 is close to a surface (also the bottom surface 220PB) of the outer dielectric layer 210 of the core redistribution layer 210-2 that is close to the bottom surface 220PB of the core structure 220P.

In other words, the terminal 604T2 of the conductive material 604 in the hole TH14 is close to an inner surface (also the inner surface 210-2B of the core redistribution layer 210-2) of one of the dielectric layers 210 of the core redistribution layer 210-2 that is close to the core 202. The terminal 606T1 of the conductive material 606 in the hole TH23 is close to an outer surface (also the bottom surface 220PB) of the one of the dielectric layers 210 of the core redistribution layer 210-1 that is away from the core 202.

In some embodiments, in the direction D120, a dimension L14 of the conductive material 604 is substantially equal to the total thickness of the cores 202, 302, 402 and the additional dielectric layers 210 between the cores 202, 302 and 402. In addition, a dimension L23 of the conductive material 606 is substantially equal to the total thickness of the cores 202, 302, 402, the additional dielectric layers 210 between the cores 202, 302 and 402, and the core redistribution layers 210-1 and 210-2. Therefore, the dimension L14 of the conductive material 604 is smaller than the dimension L23 of the conductive material 606.

In some embodiments, the conductive materials 204, 206, 404, 406, 604 and 606 may have the same or similar materials and processes.

As shown in FIG. 14, the semiconductor structure 500P further includes a non-conductive material 605 (including non-conductive material portions 605-1, 605-2) filling the remaining spaces of the holes TH14 and TH23 and surrounded by the conductive materials 604, 606. For example, the non-conductive material portion 605-1 may fill the hole TH14 and be surrounded by the conductive material 604. In addition, the non-conductive material portion 605-2 may fill the hole TH23 and be surrounded by the conductive material portion 606. In some embodiments, the non-conductive material 205, 405, 505-1 and 605 may have the same or similar materials and processes.

In this embodiment, the electrical connections among the conductive material 604, the core redistribution layers 210-1, 210-2 and the substrate redistribution layer 230-1, 230-2 may refer to the electrical connections among the conductive material 204, the core redistribution layers 210-1, 210-2 and the substrate redistribution layer 230-1, 230-2 of the semiconductor structure 500A and are not repeated for brevity. In this embodiment, the electrical connections among the conductive material 606 and the substrate redistribution layer 230-1, 230-2 may refer to the electrical connections among the conductive material 206 and the substrate redistribution layer 230-1, 230-2 of the semiconductor structure 500A and are not repeated for brevity.

In some embodiments, the substrate 200P of the semiconductor structure 500P provides various types of conductive lines for power transmission and signal transmission. In some embodiments, the conductive material 604 in the hole TH14 passing through the cores of the core structure 220P, the conductive traces of the conductive layer 208 and the vias 212 of the core redistribution layers 210-1 and 210-2, and the conductive traces of the conductive layer 224-1 and the vias 222-1 of the substrate redistribution layers 230-1 and 230-2 may form a conductive routing PH14 (also called the power routing PH14) for power transmission. For example, the power routing PH14 may include positive power supply voltage VDD, ground power supply voltage VSS, overdriven voltage signals (e.g., signals greater than VDD), negative power supply voltage signals, and other power supply voltage signals. In some embodiments, corresponding to the material and process characteristics of the dielectric layers 210 and 230, the routing density of the conductive routing PH14 in the core redistribution layers 210-1 and 210-2 is lower than that of the conductive routing PH14 in the substrate redistribution layers 230-1 and 230-2. For example, the conductive traces of the conductive layer 208 of the core redistribution layers 210-1 and 210-2 have the wider minimum line width and larger spacing than the conductive traces of the conductive layer 224-1 of the conductive routing PH14 in the substrate redistribution layers 230-1 and 230-2. Moreover, the diameter D1 of the vias 212 of the conductive routing PH14 in the core redistribution layers 210-1 and 210-2 is larger than the diameter D2 of the vias 222-1 of the conductive routing PH14 in the substrate redistribution layers 230-1 and 230-2. Therefore, the conductive routing PH14 has improved power integrity and is suitable for power transmission.

In addition, the conductive material 606 in the hole TH23 passing through the core structure 220P, and the conductive traces of the conductive layer 224-2 and the vias 222-2 of the substrate redistribution layers 230-1 and 230-2 may form a conductive routing PH23 for signal transmission (also called the signal routing PH23). Since the conductive material 606 is formed in the hole TH23 passing through the core 202 and the whole dielectric layers 210 of the core redistribution layers 210-1 and 210-2, the conductive routing PH23 may have fewer interfaces between vias and connected conductive traces of the redistribution layers (e.g., the conductive routing PH23 may be formed without the conductive traces of the conductive layer 208 and the vias 212 of the core redistribution layers 210-1 and 210-2). Therefore, the conductive routing PH23 has improved signal integrity and is suitable for signal transmission.

Since the core structure 220P is a composite structure composed of the core 202 and the dielectric layer 210 disposed on opposite surfaces of the cores 202, 302 and 402 and formed of prepreg (PP), the mechanical strength of the substrate 200P is improved. In addition, the conductive material 604 passing through the cores 202, 302 and 402 only and the conductive material 606 passing through the core structure 220P may form the conductive routings PH14 and PH23 suitable for power transmission and signal transmission. Therefore, the semiconductor structure 500P can balance between power integrity and signal integrity.

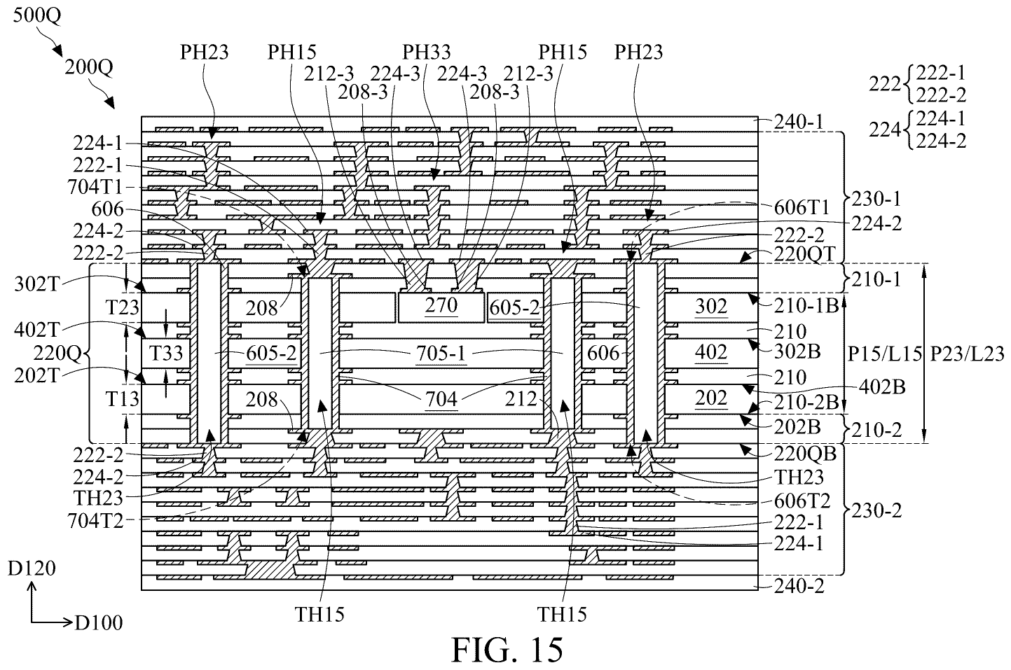

FIG. 15 is a schematic cross-sectional view of a semiconductor structure 500Q in accordance with some embodiments of the disclosure. Elements of the embodiments hereinafter, that are the same or similar as those previously described with reference to FIGS. 1, 5, 11 and 14, are not repeated for brevity.

As shown in FIGS. 14 and 15 the difference between the semiconductor structure 500H and the semiconductor structure 500Q at least includes a substrate 200Q of the semiconductor structure 500Q further includes an integrated passive device (IPD) 270 embedded in the core 302 of the core structure 220Q. In addition, the core redistribution layer 210-1 may further include vias 212-3 and conductive layers 208-3, and the substrate redistribution layer 230-1 may further include vias (not shown) and the conductive layers 224-3 to be coupled to the integrated passive device 270. In addition, a conductive material (through hole conductive component) 704 of the substrate 200Q is disposed in a hole TH15 passing through the cores 202, 302 and 402 and the three dielectric layers 210 on opposite surfaces of the cores 202, 302 and 402.

As shown in FIG. 15, the core structure 220Q of the substrate 200Q further include the hole TH15 passing through the cores 202, 302 and 402 the additional dielectric layer 210 between the cores 202, 302 and 402 and the innermost dielectric layers 210 of the core redistribution layer 210-1 and 210-2. In some embodiments, in the direction D120, the depth P15 of the hole TH15 is substantially equal to the total thickness of the cores 202, 302 and 402, the additional dielectric layer 210 between the cores 202, 302 and 402 and the innermost dielectric layers 210 of the core redistribution layer 210-1 and 210-2. The depth P15 of the hole TH15 is smaller than the depth P23 of the hole TH23.

In other words, the core structure 220Q of the substrate 200Q includes at least three cores 202, 302 and 402 and at least six dielectric layers 210 stacked on each other. In addition, the three cores 202, 302 and 402 are arranged in such a way that they alternate with four of the six dielectric layers 210. Moreover, the remaining two dielectric layers 210 are positioned as the top and bottom layers of the core structure 220Q. In some embodiments, the core structure 220Q has a hole TH15 passing through the three cores 202, 302 and 402 and middle four of the six dielectric layers 210. In addition, the core structure 220Q has a hole TH22 passing through the three cores 202, 302 and 402 and the six dielectric layers 210.

The conductive material 704 is disposed in the hole TH15, and the non-conductive material 705-1 filling the remaining spaces of the hole TH15. In some embodiments, as shown in FIG. 15, the conductive material 704 in the hole TH15 may have a hollow pillar shape. For example, the conductive material 704 may also be called a plated through hole (PTH) 704.

In this embodiment, two terminals 704T1, 704T2 of the conductive material 704 in the hole TH15 are not aligned with two corresponding terminals 606T1, 606T2 of the conductive material 606 in the hole TH23 in the direction D100. For example, the two terminals 704T1, 704T2 of the conductive material 704 in the hole TH15 may be close to and exposed from the outer surfaces of the dielectric layers 210 on the top surface 302T of the core 302 and the bottom surface 202B of the core 202, respectively.

In some embodiments, the terminal 704T1 of the conductive material 704 in the hole TH15 and the terminal 606T1 of the conductive material 606 in the hole TH23 are close to opposite surfaces of the outermost dielectric layer 210 of the core redistribution layer 210-1.

In other words, the terminal 704T1 of the conductive material 704 in the hole TH15 is close to an inner surface of the outermost dielectric layers 210 of the core redistribution layer 210-1 that is close to the core 302. The terminal 606T1 of the conductive material 606 in the hole TH23 is close to an outer surface (also the top surface 220QT) of the outermost dielectric layers 210 of the core redistribution layer 210-1 that is away from the core 302.

Similarly, the terminal 704T2 of the conductive material 704 in the hole TH15 and the terminal 606T2 of the conductive material 606 in the hole TH23 are close to opposite surfaces of any of the dielectric layers 210 of the core redistribution layer 210-2. For example, the terminal 704T2 of the conductive material 704 in the hole TH15 is close to a surface of the outermost dielectric layer 210 of the core redistribution layer 210-2 that is close to the bottom surface 202B of the core 202. The terminal 606T2 of the conductive material 606 in the hole TH23 is close to a surface (also the bottom surface 220QB) of the outermost dielectric layer 210 of the core redistribution layer 210-2 that is close to the bottom surface 220QB of the core structure 220Q.

In other words, the terminal 704T2 of the conductive material 704 in the hole TH15 is close to an inner surface of the outermost dielectric layers 210 of the core redistribution layer 210-2 that is close to the core 202. The terminal 606T1 of the conductive material 606 in the hole TH23 is close to an outer surface (also the bottom surface 220QB) of the outermost dielectric layers 210 of the core redistribution layer 210-1 that is away from the core 202.

In some embodiments, in the direction D120, a dimension L15 of the conductive material 704 is substantially equal to the total thickness of the cores 202, 302, 402 and the additional dielectric layer 210 on the opposite surfaces of the cores 202, 302 and 402. The dimension L15 of the conductive material 704 is smaller than the dimension L23 of the conductive material 606.

In some embodiments, the conductive materials 204, 206, 404, 406, 704, 604, and 606 may have the same or similar materials and processes. In some embodiments, the non-conductive material 205, 405, 505-1, 605 and 705-1 may have the same or similar materials and processes.

In some embodiments, the integrated passive device 270 of the semiconductor structure 500Q is disposed embedded in the core close to the top surface 220QT or the bottom surface 220QT of the core structure 220Q. As shown in FIG. 15, the integrated passive device 270 is disposed embedded in the core 302 of the core structure 220Q of the substrate 200Q. The core 302 is close to the top surface 220QT of the core structure 220Q. For example, the integrated passive device 270 is disposed in a cavity (not shown) of the core 302. In addition, pads (not shown) of the integrated passive device 270 may be exposed form the top surface 302T of the core 302. In this embodiment, the pads (not shown) of the integrated passive device 270 may be exposed form the top surface 302T of the core 302. Furthermore, the dielectric layer 210 may fill the remaining space between sidewalls (not shown) of the integrated passive device 270 and the core 302 (e.g., the sidewalls of the cavity) for the isolation between the integrated passive device 270 and the core 302.

Alternatively, the integrated passive device 270 may be disposed embedded in the core 202 of the core structure 220Q of the substrate 200Q. The core 202 is close to the bottom surface 220QB of the core structure 220Q. For example, the integrated passive device 270 is disposed in a cavity (not shown) of the core 202. In addition, pads (not shown) of the integrated passive device 270 may be exposed form the bottom surface 202B of the core 202. In this embodiment, the pads (not shown) of the integrated passive device 270 may be exposed form the bottom surface 202B of the core 202. Furthermore, the dielectric layer 210 may fill the remaining space between sidewalls (not shown) of the integrated passive device 270 and the core 202 (e.g., the sidewalls of the cavity) for the isolation between the integrated passive device 270 and the core 202.

Since there is no via and/or conductive trace (not shown) positioned in the two additional dielectric layers 210 between the cores 302 and 402 and between the cores 202 and 402, the integrated passive device 270 is not disposed embedded in the core 402 of the core structure 220Q of the substrate 200Q.

In some embodiments, the integrated passive device 270 is coupled to the vias and the conductive layers of the core redistribution layer 210-1 (or the core redistribution layer 210-2) and the substrate redistribution layer 230-1 (or the substrate redistribution layer 230-2) face (close to) the pads of the conductive layers 270. For example, when the pads (not shown) of the integrated passive device 270 may be exposed form the top surface 302T of the core 302, the pads of the conductive layers 270 are coupled to the vias 212-3 and the conductive layers 208-3 disposed in the dielectric layers 210 of the core redistribution layer 210-1 and the vias (not shown) and the conductive layers 224-3 disposed in the dielectric layers 230 of the substrate redistribution layer 230-1. The vias 212-3 and the conductive layers 208-3 of the core redistribution layer 210-1 and the vias (not shown) and the conductive layers 224-3 of the substrate redistribution layer 230-1 are disposed on (and close to) the top surface 302T of the core 302.

Alternatively, when the pads (not shown) of the integrated passive device 270 may be exposed form the bottom surface 202B of the core 202, the pads of the conductive layers 270 are coupled to vias (not shown) and conductive layers 224-3 disposed in the dielectric layers 210 of the core redistribution layer 210-2 and vias (not shown) and conductive layers 224-3 disposed in the dielectric layers 230 of the substrate redistribution layer 230-2. The vias and the conductive layers of the core redistribution layer 210-2 and the substrate redistribution layer 230-2 are disposed on (and close to) the bottom surface 202B of the core 202.

In this embodiment, the conductive traces of the conductive layer 208-3 and the vias 212-3 of the core redistribution layers 210-1, and the conductive traces of the conductive layer 224-3 and the vias (not shown) of the substrate redistribution layers 230-1 may form a conductive routing PH33 (also called the power routing PH33) coupled to the conductive routing PH15 or the conductive routing PH23.

In some embodiments, the substrate 200Q of the semiconductor structure 500Q provides various types of conductive lines for power transmission and signal transmission. In some embodiments, the conductive material 704 in the hole TH15, the conductive traces of the conductive layer 208 and the vias 212 of the core redistribution layers 210-1 and 210-2, and the conductive traces of the conductive layer 224-1 and the vias 222-1 of the substrate redistribution layers 230-1 and 230-2 may form a conductive routing PH15 (also called the power routing PH15) for power transmission. In some embodiments, corresponding to the material and process characteristics of the dielectric layers 210 and 230, the routing density of the conductive routing PH15 in the core redistribution layers 210-1 and 210-2 is lower than that of the conductive routing PH15 in the substrate redistribution layers 230-1 and 230-2. Therefore, the conductive routing PH15 has improved power integrity and is suitable for power transmission.

Since the core structure 220Q is a composite structure composed of the cores 202, 302 and 402 and the dielectric layers 210 disposed on opposite surfaces of the cores 202, 302 and 402 and formed of prepreg (PP), the mechanical strength of the substrate 200Q is improved. In addition, the conductive material 704 passing through the cores 202, 302 and 402 and the middle four dielectric layers 210 only and the conductive material 606 passing through the core structure 220Q may form the conductive routings PH15 and PH23 suitable for power transmission and signal transmission. Therefore, the semiconductor structure 500Q can balance between power integrity and signal integrity.

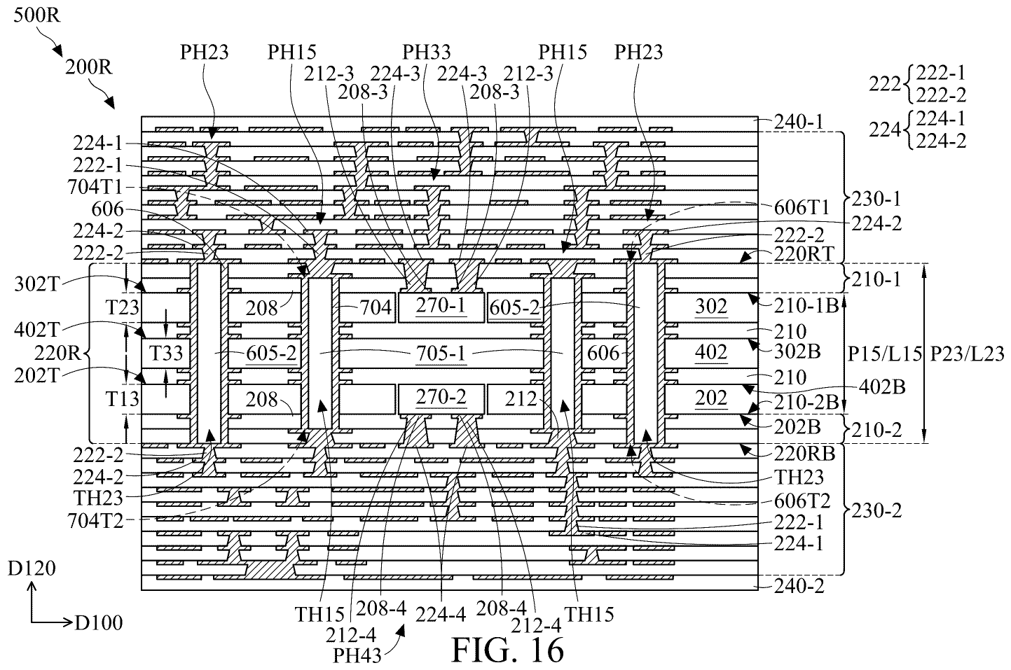

FIG. 16 is a schematic cross-sectional view of a semiconductor structure 500R in accordance with some embodiments of the disclosure. Elements of the embodiments hereinafter, that are the same or similar as those previously described with reference to FIGS. 1, 5, 11, 12, 14 and 15, are not repeated for brevity.

As shown in FIGS. 15 and 16, the difference between the semiconductor structure 500J and the semiconductor structure 500R at least includes that a core structure 220R of a substrate 200R of the semiconductor structure 500R further includes an integrated passive device (IPD) 270-1 embedded in the core 302 and an integrated passive device (IPD) 270-2 embedded in the core 202. In addition, the core redistribution layer 210-1 may further include vias 212-3 and conductive layers 208-3, and the substrate redistribution layer 230-1 may further include vias (not shown) and the conductive layers 224-3 to be coupled to the integrated passive device 270-1. Moreover, the core redistribution layer 210-2 may further include vias 212-4 and conductive layers 208-4, and the substrate redistribution layer 230-2 may further include vias (not shown) and the conductive layers 224-4 to be coupled to the integrated passive device 270-2.

In some embodiments, the integrated passive device 270-1 and 270-2 of the semiconductor structure 500R are disposed embedded in the cores 202 and 302 close to the top surface 220RT and the bottom surface 220BT of the core structure 220R. As shown in FIG. 16, the integrated passive device 270-1 is disposed embedded in the core 302 of the core structure 220R of the substrate 200F. The core 302 is close to the top surface 220RT of the core structure 220R. For example, the integrated passive device 270-1 is disposed in a cavity (not shown) of the core 302. In addition, pads (not shown) of the integrated passive device 270-1 may be exposed form the top surface 302T of the core 302. In this embodiment, the pads (not shown) of the integrated passive device 270-1 may be exposed form the top surface 302T of the core 302. Furthermore, the dielectric layer 210 may fill the remaining space between sidewalls (not shown) of the integrated passive device 270-1 and the core 302 (e.g., the sidewalls of the cavity) for the isolation between the integrated passive device 270-1 and the core 302.

As shown in FIG. 16, the integrated passive device 270-2 may be disposed embedded in the core 202 of the core structure 220R of the substrate 200F. The core 202 is close to the bottom surface 220RB of the core structure 220R. For example, the integrated passive device 270-2 is disposed in a cavity (not shown) of the core 202. In addition, pads (not shown) of the integrated passive device 270-2 may be exposed form the bottom surface 202B of the core 202. In this embodiment, the pads (not shown) of the integrated passive device 270-2 may be exposed form the bottom surface 202B of the core 202. Furthermore, the dielectric layer 210 may fill the remaining space between sidewalls (not shown) of the integrated passive device 270-2 and the core 202 (e.g., the sidewalls of the cavity) for the isolation between the integrated passive device 270-2 and the core 202.

Since there is no via and/or conductive trace (not shown) positioned in the two additional dielectric layers 210 between the cores 302 and 402 and between the cores 202 and 402, the integrated passive device 270 is not disposed embedded in the core 402 of the core structure 220R of the substrate 200R.

In some embodiments, the integrated passive devices 270-1 and 270-2 are coupled to the vias and the conductive layers of the core redistribution layers 210-1, 210-2 and the substrate redistribution layers 230-1, 230-2 face (close to) the pads of the conductive layers 270-1 and 270-2. As shown in FIG. 16, the pads (not shown) of the conductive layers 270-1 are coupled to the vias 212-3 and the conductive layers 208-3 disposed in the dielectric layers 210 of the core redistribution layer 210-1 and the vias (not shown) and the conductive layers 224-3 disposed in the dielectric layers 230 of the substrate redistribution layer 230-1. The vias 212-3 and the conductive layers 208-3 of the core redistribution layer 210-1 and the vias (not shown) and the conductive layers 224-3 of the substrate redistribution layer 230-1 are disposed on (and close to) the top surface 302T of the core 302.

As shown in FIG. 16, the pads of the conductive layers 270-2 are coupled to vias 212-4 and conductive layers 208-4 disposed in the dielectric layers 210 of the core redistribution layer 210-2 and vias (not shown) and conductive layers 224-4 disposed in the dielectric layers 230 of the substrate redistribution layer 230-2. The vias and the conductive layers of the core redistribution layer 210-2 and the substrate redistribution layer 230-2 are disposed on (and close to) the bottom surface 202B of the core 202.

In this embodiment, the conductive traces of the conductive layer 208-3 and the vias 212-3 of the core redistribution layers 210-1, and the conductive traces of the conductive layer 224-3 and the vias (not shown) of the substrate redistribution layers 230-1 may form a conductive routing PH33 (also called the power routing PH33) coupled to the conductive routing PH15 or the conductive routing PH23. In addition, the conductive traces of the conductive layer 208-4 and the vias 212-4 of the core redistribution layers 210-2, and the conductive traces of the conductive layer 224-4 and the vias (not shown) of the substrate redistribution layers 230-2 may form a conductive routing PH43 (also called the power routing PH43) coupled to the conductive routing PH15 or the conductive routing PH23.

In some embodiments, the conductive materials 404, 704, 704 and 704 of the semiconductor structures 500E-500H, 500J and 500R may be replaced by a conductive solid pillar (e.g., a copper pillar) similar to the conductive material 304 of the semiconductor structures 500B and 500D (FIGS. 2 and 4).

The semiconductor structures 500E-500H, 500J and 500R include multi-layer multi-core substrates 200E-200H, 200J and 200R in which the core structures are composed of a plurality of cores. The core structure of each of the substrates 200E-200H, 200J and 200R includes at least two cores arranged in such a way that they alternate with the three dielectric layers formed of prepreg (PP). In some embodiments, the core structure has a first hole (e.g., the holes TH12, TH13, TH14, TH14) passing through the two cores and the dielectric layer(s) between the cores. In addition, the core structure has a second hole (e.g., the holes TH22, TH23) passing through the three cores 202, 302, 402 and the three dielectric layers 210.

Beside the advantages of the semiconductor structures 500A to 500D, the multi-core substrate of each of the semiconductor structures 500E-500H, 500J and 500R include a plurality of cores and the dielectric layers between the cores. The dielectric layers between the cores formed of, example, prepreg (PP), may improve the mechanical strength of the core structure to withstand various external forces without breaking or yielding. Therefore, the thickness of each of the cores in the multi-core structure may be thinner than the thickness of the single core in the single-core structure to satisfy the limitation of the substrate height. The semiconductor structures may have improved mechanical strength and the adjustable thickness.

In addition, the semiconductor structures 500L to 500M, 500P to 500R may enhances both power integrity and signal integrity performance through denser conductive materials in the first holes (e.g., the holes TH12, TH13, TH14, TH14) with shorter lengths. Moreover, the semiconductor structures 500L-500M, 500P-500R having improved mechanical strength may simplify semiconductor bonding technology (SBT) manufacturing processes. Furthermore, the semiconductor structures 5500L to 500M, 500P to 500R may applied mixed plated through hole (PTH) or conductive pillar design in a multi-layer core substrate.

Embodiments provides a semiconductor structure. The semiconductor structure includes a substrate. The substrate includes a first core having a first top surface and a first bottom surface. First dielectric layers are disposed on the first top surface and the first bottom surface of the first core. The substrate has a first hole passing through the first core, and a second hole passing through the first core and the first dielectric layers.

In some embodiments, the substrate further includes a first conductive material disposed in the first hole. The substrate further includes a second conductive material disposed in the second hole. In a first direction, a first dimension of the first conductive material is smaller than a second dimension of the second conductive material.

In some embodiments, a first terminal of the first conductive material and a second terminal of the second conductive material corresponding to the first terminal are close to opposite surfaces of one of the first dielectric layers.

In some embodiments, the first terminal of the first conductive material is close to an inner surface of one of the first dielectric layers close to the first core, and the second terminal of the second conductive material is close to an outer surface of the one of the first dielectric layers away from the first core.

In some embodiments, the substrate further includes: second dielectric layers disposed on the first dielectric layers and opposite to the first core. The first dielectric layers and the second dielectric layers are made of different materials.

In some embodiments, the substrate further includes a first via disposed in the first dielectric layer and coupled to the first conductive material by a first conductive trace covered by the first dielectric layer. The substrate further includes a second via disposed in the second dielectric layer and coupled to the second conductive material by a second conductive trace covered by the second dielectric layer.

In some embodiments, the first via has a first diameter, and the second via has a second diameter. The second diameter is smaller than the first diameter.

In some embodiments, the first via and the first conductive trace are used for signal transmission.

In some embodiments, the second via and the second conductive trace are used for power transmission.

In some embodiments, the first conductive trace has a first line width, and the second conductive trace has a second line width. The second line width is smaller than the first line width.

In some embodiments, the substrate further includes a first integrated passive device embedded in the first core. The first integrated passive device is coupled to a third via and a third conductive trace disposed in the first dielectric layers on the top surface of the first core.

In some embodiments, the substrate further includes a second core disposed on the first core. One of the first dielectric layers is disposed between the first core and the second core.

In some embodiments, another one of the first dielectric layers is disposed on the second core and opposite to the one of the first dielectric layers.

In some embodiments, the first hole further passes through the second core and the one of the first dielectric layers, and the second hole further passes through the second core and all of the first dielectric layers.

In some embodiments, the first hole further passes through the other first dielectric layer.

In some embodiments, the substrate further includes a first integrated passive device embedded in the first core. The substrate further includes a second integrated passive device embedded in the second core. The first integrated passive device is separated from the second integrated passive device.

In some embodiments, the first integrated passive device and the second integrated passive device are coupled to vias and conductive traces disposed in the first dielectric layers on the top and bottom surfaces of the first dielectric layers, except for the one of the first dielectric layers.

In some embodiments, the first conductive material and the second conductive material have a hollow pillar shape or a solid pillar shape.

Embodiments provides a semiconductor structure. The semiconductor structure includes a substrate. The substrate includes a core structure. The core structure includes at least two cores and at least three first dielectric layers stacked on each other. The two cores are arranged in such a way that they alternate with the three first dielectric layers. The substrate has a first conductive material passing through the first core and one of the first dielectric layers, and a second conductive material passing through the first core and all of the first dielectric layers.

In some embodiments, the first conductive material is used for signal transmission, and the second conductive material is used for power transmission.

In some embodiments, the substrate further includes an integrated passive device embedded in one of the cores. The first integrated passive device is coupled to conductive traces disposed in one of the first dielectric layers that is close to the top surface or the bottom surface of the core structure.

In some embodiments, the substrate further includes at least two second dielectric layers disposed on a top surface and a bottom surface of the core structure and connected to the top and bottom first dielectric layers. The three first dielectric layers and the two second dielectric layers are made of different materials.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a substrate, wherein the substrate comprises:
a first core having a first top surface and a first bottom surface;
first dielectric layers disposed on the first top surface and the first bottom surface of the first core,
wherein the substrate has a first hole passing through the first core and a second hole passing through the first core and the first dielectric layers.

2. The semiconductor structure as claimed in claim 1, wherein the substrate further comprises:
a first conductive material disposed in the first hole; and
a second conductive material disposed in the second hole, wherein in a first direction, a first dimension of the first conductive material is smaller than a second dimension of the second conductive material.

3. The semiconductor structure as claimed in claim 2, wherein a first terminal of the first conductive material and a second terminal of the second conductive material corresponding to the first terminal are close to opposite surfaces of one of the first dielectric layers.

4. The semiconductor structure as claimed in claim 1, wherein the substrate further comprises:
second dielectric layers disposed on the first dielectric layers and opposite to the first core, wherein the first dielectric layers and the second dielectric layers are made of different materials.

5. The semiconductor structure as claimed in claim 4, wherein the substrate further comprises:
a first via disposed in the first dielectric layer and coupled to the first conductive material by a first conductive layer covered by the first dielectric layer; and
a second via disposed in the second dielectric layer and coupled to the second conductive material by a second conductive layer covered by the second dielectric layer.

6. The semiconductor structure as claimed in claim 5, wherein the first via has a first diameter, and the second via has a second diameter, which is smaller than the first diameter.

7. The semiconductor structure as claimed in claim 5, wherein the first via and the first conductive layer are used for power transmission.

8. The semiconductor structure as claimed in claim 5, wherein the second via and the second conductive layer are used for signal transmission.

9. The semiconductor structure as claimed in claim 5, wherein the first conductive layer has a first line width, and the second conductive layer has a second line width, which is smaller than the first line width.

10. The semiconductor structure as claimed in claim 1, wherein the substrate further comprises:
a first integrated passive device embedded in the first core, wherein the first integrated passive device is coupled to a third via and a third conductive layer disposed in the first dielectric layers on the top surface of the first core.

11. The semiconductor structure as claimed in claim 1, wherein the substrate further comprises:
a second core disposed on the first core, wherein one of the first dielectric layers is disposed between the first core and the second core.

12. The semiconductor structure as claimed in claim 11, wherein another one of the first dielectric layers is disposed on the second core and opposite to the one of the first dielectric layers.

13. The semiconductor structure as claimed in claim 12, wherein the first hole further passes through the second core and the one of the first dielectric layers, and the second hole further passes through the second core and all of the first dielectric layers.

14. The semiconductor structure as claimed in claim 13, wherein the first hole further passes through the other one of the first dielectric layers.

15. The semiconductor structure as claimed in claim 11, wherein the substrate further comprises:
a first integrated passive device embedded in the first core;
a second integrated passive device embedded in the second core, wherein the first integrated passive device is separated from the second integrated passive device.

16. The semiconductor structure as claimed in claim 15, wherein the first integrated passive device and the second integrated passive device are coupled to vias and conductive traces disposed in the first dielectric layers on the top and bottom surfaces of the first dielectric layers, except for the one of the first dielectric layers.

17. A semiconductor structure, comprising:
a substrate, wherein the substrate comprises:
a core structure, wherein the core structure comprises:
at least two cores and at least three first dielectric layers stacked on each other, wherein the at least two cores are arranged in such a way that they alternate with the at least three first dielectric layers,
wherein the core structure has a first conductive material passing through the at least two cores and one of the at least three first dielectric layers, and a second conductive material passing through the at least two cores and the at least three first dielectric layers.

18. The semiconductor structure as claimed in claim 17, wherein the first conductive material is used for signal transmission, and the second conductive material is used for power transmission.

19. The semiconductor structure as claimed in claim 17, wherein the substrate further comprises:
an integrated passive device embedded in one of the at least two cores, wherein the integrated passive device is coupled to conductive traces disposed in one of the at least three first dielectric layers close to a top surface or a bottom surface of the core structure.

20. The semiconductor structure as claimed in claim 17, wherein the substrate further comprises:
at least two second dielectric layers disposed on a top surface and a bottom surface of the core structure and connected to a top one and a bottom one of the at least three first dielectric layers, wherein the at least three first dielectric layers and the at least two second dielectric layers are made of different materials.
